(19) United States
(12) Patent Application Publication
(10) Pub. No.: US 2025/0180766 A1
(43) Pub. Date: Jun. 5, 2025

(54) Semiconductor Neutron Detectors

(71) Applicant: Texas Tech University System, Lubbock, TX (US)

(72) Inventors: Hongxing Jiang, Lubbock, TX (US); Jing Li, Lubbock, TX (US); Jingyu Lin, Lubbock, TX (US); Attasit Tingsuwatit, Lubbock, TX (US)

(21) Appl. No.: 18/845,544

(22) PCT Filed: Mar. 14, 2023
(86) PCT No.: PCT/US2023/064305

§ 371 Date: Sep. 10, 2024

Related U.S. Application Data
(60) Provisional application No. 63/319,988, filed on Mar. 15, 2022.

(51) Int. Cl. G01T 3/08; H10F 30/292; H10F 39/90; H10F 71/00; H10F 77/124; H10F 77/50

(52) U.S. Cl. CPC G01T 3/08; H10F 30/292; H10F 39/90; H10F 71/1276; H10F 71/1278; H10F 77/1246; H10F 77/50

(57) ABSTRACT

A neutron detector for detecting neutrons with energies from meV to tens of MeV comprising one or more nitride (BN) strips electrically connected in parallel or series. In some embodiments, the two or more BN strips are stacked on one another. In other embodiments, the two or more BN strips are disposed on a substrate with a gap between the two or more BN strips.

### CROSS-REFERENCE TO RELATED APPLICATIONS

This application claims priority to U.S. Provisional Application Ser. No. 63/319,988, filed Mar. 15, 2022, the entire contents of which are incorporated herein by reference.

### STATEMENT OF FEDERALLY FUNDED RESEARCH

This invention was made with government support under Grant/Contract Nos. DE-AR0001257 and DE-AR0001552 awarded by the Department of Energy, Advanced Research Projects Agency-Energy (ARPA-E). The government has certain rights in the invention.

### TECHNICAL FIELD OF THE INVENTION

The present invention relates in general to the field of semiconductor detectors, and more particularly, to semiconductor neutron detectors capable of detecting thermal to fast neutrons.

### BACKGROUND OF THE INVENTION

Without limiting the scope of the invention, its background is described in connection with semiconductor detectors.

Effective neutron detection is one of the key technologies that support safe nuclear power generation based on either fusion or fission, including monitoring nuclear reactors, and identifying nuclear fuels. More specifically, fast neutron detection technologies provide a critical means for monitoring the neutron fluxes from fissile and fusion power generation systems and to assure radiation safety to the public [1-5]. Neutron detectors also have many other applications, including nuclear security, nuclear waste management, oil field exploration, and life search in space. As such, much R & D effort has been devoted to the development of highly efficient and robust neutron detectors over the last several decades. Detection of fast neutrons with energies above 1 MeV, however, is still regarded technically challenging due to their intrinsically much lower interaction probabilities with all matters than thermal neutrons (slow neutrons with an energy of 0.025 eV or 25 meV). The ideal neutron detector should be compact to allow its optimal positioning, fissile-material-free for security reasons and ease of operation, radiation, and temperature resistant to allow operation in harsh environments, such as in the vicinity or core of a nuclear reactor. Ideally, it should also be simultaneously sensitive to neutrons with energies ranging from thermal and fast neutrons. However, neutron detectors in the present existing market, including fission chambers, gas counters, and silicon detectors, fail in at least one of these requirements.

Neutron radiations from nuclear reactors and other sources mostly consist of fast neutrons. However, the interaction probabilities of fast neutrons with all matters are very low with a typical interaction cross-section of only a few Barns [6-8]. Therefore, technologies for monitoring fast neutrons are rather primitive. Instead, many types of neutron detectors have been developed to detect slow neutrons (from thermal to epithermal neutrons) using sensing elements of ³He, ⁶Li and ¹⁰B because the reaction rates or capture cross-sections of slow neutrons with ³He (or He-3), ⁶Li (or Li-6) and ¹⁰B (or B-10) are much larger than those of fast neutrons [9-25]. As illustrated in FIG. 1A, in order to monitor fast neutron radiation, the present techniques typically employ a large volume of neutron conversion material such as a large high-density polyethylene (HDPE) sphere to first convert fast neutrons to thermal neutrons and then a thermal neutron detector is used to detect the neutron signal. This large HDPE performs the function to convert fast neutrons to thermal neutrons. Many incoming fast neutrons are lost during this conversion process. Because the cross-section for thermal neutrons is 3 orders of magnitudes higher than those of fast neutrons, thermal neutron detectors can provide a reasonable detection efficiency as well as a count rate by utilizing this conversion process. However, the disadvantages of such neutron detectors include bulky, heavy, nonportable, fixed operation range and not convenient to operator. In another practical application scenario, as shown in FIG. 1B, a typical well logging toll needs to employ multiple thermal, epithermal, and far epithermal neutron detectors based on ³He gas tubes, which makes the tools costly and bulky. More seriously, the world is experiencing a shortage of ³He gas because the demand for ³He has been dramatically increased over the last decade in response to the steady increasing in demand due to the deployment for cargo screening in the ports of entry and on ships [5], not to mention that ³He gas itself is a byproduct or nuclear waste from nuclear weapons production.

On the other hand, organic scintillators made of hydrogenous materials are commonly used to detect fast neutrons indirectly from scintillation lights created by elastically scattered proton recoils inside the scintillator volumes. Typically, scintillators exhibit higher neutron interaction rates, but they come in large volumes to completely stop the energetic proton recoils and often require high bias voltage for photomultiplier tubes to collect scintillation lights. Scintillators are also known to suffer from efficiency loss and non-linear scintillation output at high temperatures.

For slow thermal neutrons, semiconductor neutron detectors are considered the best candidate for low-mass, low-power and harsh environment applications [9-34]. Most semiconductor thermal neutron detectors use a thin neutron conversion layer of ⁶Li or ¹⁰B [9-22]. The limitation of this approach is that the thin layer itself prevents neutron reaction products from depositing all their energies in the semiconductor detector's sensitive volume, which limits the detection efficiency and results in poor energy resolution. While ¹⁰B and ⁶Li filled micro-structured semiconductor neutron (MSN) detectors have attained a detection efficiency for thermal neutrons of 30% [14-16, 25], this technology, however, is not suitable for fast neutron detection.

Accordingly there is a need for a new semiconductor neutron detector capable of detecting thermal to fast neutrons.

### SUMMARY OF THE INVENTION

Neutrons or neutron sources, which need to be detected and analyzed, almost all involve fast neutrons. These include application areas of nuclear reactors, radiation waste management, neutron generators, neutron radiography and scattering, and space exploration. The present disclosure relates to the design and fabrication of BN neutron detectors with ability for simultaneously detecting neutrons with energies ranging from those of thermal to fast neutrons as well as with high intrinsic and charge collection efficiencies.

The physics principle of the presently disclosed neutron detector for detecting fast neutrons is based on charge carrier generation via recoil B and N ions upon elastic scattering by incoming fast neutrons and the subsequent collection of these charge carriers in BN, whereas that for detecting slow thermal neutrons is based on the nuclear reaction between the isotope ¹⁰B in BN and thermal neutrons. The element B exists as two main isotopes, ¹⁰B and ¹¹B in a natural abundance of approximately 20% and 80% respectively [24] and it is only the isotope ¹⁰B that can interact with thermal neutrons. BN semi-bulk crystals are used to fabricate the BN neutron detectors disclosed here via standard semiconductor processing tools. The detector design schemes disclosed here enable high intrinsic and charge collection efficiencies. BN neutron detectors are constructed by stacking up multiple BN blocks of about 1 mm in thickness. BN detectors are expected to possess advantages of compact size, portable, low cost, and easy to operate. With BN semiconductor detectors, the bulky neutron conversion HDPE sphere shown in FIG. 1A will be removed. With their ability to simultaneously detecting thermal to fast neutrons, a single BN neutron detector has the potential to replace the multiple He-3 gas detectors in well logging tools such as that shown in FIG. 1B. It can be envisioned that BN detectors disclosed here can be installed in the vicinity of a nuclear reactor for monitoring the states of nuclear power generation and fuels because of their compactness, and radiation and temperature resistance.

One embodiment of the present disclosure provides a neutron detector that includes one or more boron nitride (BN) strips electrically connected in parallel or series.

In one aspect, each of the one or more BN strips has a width (W) of about 1 to 10 mm, a length (L) of about 10 to 50 mm, and a thickness (d) or height (H) of about 0.1 mm to 10 mm thick. In another aspect, the one or more BN strips comprise Boron-10 enriched boron nitride or natural BN crystals. In another aspect, the one or more BN strips comprise 1, 2, 3, 4, 5, 6, 7, 8, 9, 10, 11, 12 or more intermediate BN strips. In another aspect, the neutron detector includes a housing enclosing the one or more BN strips. In another aspect, the neutron detector includes a gamma-ray shield disposed around the housing. In another aspect, the one or more BN strips comprise two or more BN strips stacked on one another. In another aspect, the neutron detector includes a metal contact disposed on a top and a bottom of the two or more BN strips, and the two or more BN strips are connected together through the metal contacts in parallel or series to support a charge transport in a vertical direction with respect to planes of the two or more BN strips. In another aspect, the neutron detector includes an intermediate substrate disposed in between each of the two or more BN strips, a lower substrate disposed on a bottom of a lower BN strip of the two or more BN strips, a first metal contact disposed on a first longitudinal side of each of the two or more BN strips, a second metal contact disposed on a second longitudinal side of each of the two or more BN strips, and the first metal contacts and second metal contacts are used to electrically connect the two or more BN strips in parallel to support a charge transport in a lateral direction with respect to planes of the two or more BN strips. In another aspect, the lower substrate is larger than each intermediate substrate, and the intermediate substrates become progressively smaller from the lower substrate to an upper BN strip. In another aspect, each intermediate substrate and the lower substrate comprise sapphire, pyrolytic BN, free-standing hexagonal BN, SiC, or polycrystalline diamond. In another aspect, the neutron detector includes one or more buffer layers disposed on top of the lower substrate and each intermediate substrate. In another aspect, the neutron detector includes one or more epitaxial layer templates disposed on top of each of the one or more buffer layers. In another aspect, the one or more epitaxial layer templates comprise AlN, BN, GaN or diamond materials. In another aspect, the neutron detector includes a substrate, the two or more BN strips are disposed on the substrate with a gap between the two or more BN strip, a first metal contact disposed on a first longitudinal side of each of the two or more BN strips, a second metal contact disposed on a second longitudinal side of each of the two or more BN strips, and the first metal contacts and second metal contacts are used to electrically connect the two or more BN strips in parallel to support a charge transport in a lateral direction with respect to the planes of two or more BN strips. In another aspect, the gap comprises 0.1 to 2 mm. In another aspect, the neutron detector includes a housing enclosing the two or more BN strips. In another aspect, the neutron detector includes a gamma-ray shield disposed around the housing. In another aspect, the substrate comprises a first substrate having a first metal pad connected to the first metal contacts and a second metal pad connected to the second metal contacts, the two or more BN stripes comprise two or more first BN strips, one or more BN assemblies disposed below the first substrate, each of the one or more BN assemblies comprise: a second BN strip, a second substrate disposed below the second BN strip, a third metal contact disposed on a first longitudinal side of the second BN strip, and a fourth metal contact disposed on a second longitudinal side of the second BN strip; and the first metal pad, the second metal pad, the third metal contacts, the fourth metal contacts are used to electrically connect the two or more first BN strips and each second BN strip in parallel. In another aspect, the first substrate and the second substrate comprise sapphire, pyrolytic BN, free-standing hexagonal BN, SiC, or polycrystalline diamond. In another aspect, the neutron detector includes one or more buffer layers disposed on top of the first substrate and the second substrate. In another aspect, the neutron detector includes one or more epitaxial layer templates disposed on top of each of the one or more buffer layers. In another aspect, the one or more epitaxial layer templates comprise AlN, BN, GaN or diamond materials.

Another embodiment of the present disclosure provides a method for detecting neutrons the neutron detector described above.

In one aspect, the detected neutrons have energies from meV to tens of MeV. In another aspect, the detected neutrons comprise thermal to fast neutrons. In another aspect, the fast neutrons are converted to thermal neutrons by adding a block of HDPE material around the neutron detector to distinguish thermal neutrons from fast neutrons. In another aspect, it is determined whether a neutron source comprises a thermal neutron source or a fast neutron source based on a change in a counting rate of the thermal neutrons after adding the block of HDPE material.

Another embodiment of the present disclosure provides a method of fabricating a boron nitride (BN) layer by depositing one or more buffer layers on a substrate, and growing the BN layer on the one or more buffer layers.

In one aspect, the substrate comprises sapphire, pyrolytic BN, free-standing hexagonal BN, SiC, or polycrystalline diamond. In another aspect, the BN layer comprises Boron-10 enriched boron nitride or natural BN crystals. In another aspect a thickness of the BN layer comprises 0.1 to 10 mm. In another aspect, the BN layer is grown using hydride vapor phase epitaxy (HVPE), sputtering, pulsed laser deposition (PLD), chemical vapor deposition (CVD), or metal organic vapor deposition (MOCVD). In another aspect, one or more epitaxial layer templates are deposited on top of the one or more buffer layers prior to growing the BN layer. In another aspect, the one or more epitaxial layer templates comprise AlN, BN, GaN or diamond materials. In another aspect, the method further includes removing the BN layer, and dicing the BN layer into BN strips. In another aspect, the method further includes mounting one or more of the BN strips on sapphire substrate. In another aspect, the method further includes depositing one or more metal contacts on the BN strips.

Note that the invention is not limited to the embodiments described herein, instead it has the applicability beyond the embodiments described herein. The brief and detailed descriptions of this disclosure are given in the following.

### BRIEF DESCRIPTION OF THE DRAWINGS

For a more complete understanding of the features and advantages of the present invention, reference is now made to the detailed description of the invention along with the accompanying figures and in which:

FIG. 1A depicts an example of a fast neutron detector with a large HDPE sphere moderated He-3 gas tube in accordance with the prior art;

FIG. 1B depicts an illustration of Schlumberger's Accelerator Porosity Sonde (APS) well logging tool, which consists of a neutron generator and five He-3 gas tube neutron detectors ranging from thermal to far epithermal detectors in accordance with the prior art;

FIG. 2A is a plot of the neutron energy dependence of the nuclear interaction probabilities with neutrons (or neutron capture cross-sections) of ³He, ⁶Li and ¹⁰B nuclei [24] in accordance with one embodiment of the present disclosure;

FIG. 2B is a plot of the neutron energy dependence of the cross-sections of dominant elastic scattering of fast neutrons in BN in the energy range between 0.5 and 20 MeV for ¹⁰B, ¹¹B, and ¹⁴N [8] in accordance with one embodiment of the present disclosure;

FIG. 3 is a plot of the measured fast neutron transmission (T) as a function of BN layer thickness (d). Dots are experimental data and solid curve is a fit with Eq. (3) in accordance with one embodiment of the present disclosure;

FIG. 4 is a plot of the layer thickness dependence of the intrinsic efficiency of hexagonal BN (h-BN) detector for fast neutrons in accordance with one embodiment of the present disclosure;

FIG. 5A is an optical image of a 2.1 cm² area neutron detector fabricated from 100 μm thick B-10 enriched BN freestanding wafer by combining multiple detector strips in accordance with one embodiment of the present disclosure;

FIG. 5B is a plot of the pulse height spectra of this 2 cm² area BN detector in response to fast neutrons from a ²⁵²Cf source without the use of a HDPE moderator, covering the energy range from 1 to 9 MeV (red curve) and in the presence without any source (blue curve), all measured at bias voltage of 300 V in accordance with one embodiment of the present disclosure;

FIG. 6A is a schematic diagram of a freestanding h-BN wafer formed by self-separation from sapphire substrate during cooling down after growth by an epitaxial growth method in accordance with one embodiment of the present disclosure;

FIG. 6B is a photo of a freestanding h-¹⁰BN epilayer wafer of 4-inches in diameter in accordance with one embodiment of the present disclosure;

FIG. 7 is a schematic of a dicing scheme for a wafer of 6-inches in diameter, from which a total of 47 BN blocks each with an area of 1 cm×3 cm can be realized in accordance with one embodiment of the present disclosure;

FIG. 8 is an illustration of a BN neutron detector design supporting charge transport in the vertical direction. The neutron detector is constructed by stacking up 10 blocks of BN with a dimension of 1 cm×1 cm×3 cm in accordance with one embodiment of the present disclosure;

FIG. 9 is an illustration of a BN neutron detector design supporting charge transport in the lateral direction in accordance with one embodiment of the present disclosure;

FIG. 10A is an illustration of a BN neutron detector without incorporation of an HDPE block for identifying the nature of unknown neutron source emitting thermal or fast neutrons in accordance with one embodiment of the present disclosure;

FIG. 10B is an illustration of a BN neutron detector (with incorporation of an HDPE block for identifying the nature of unknown neutron source emitting thermal or fast neutrons in accordance with one embodiment of the present disclosure;

FIG. 11A is an illustration of a BN semi-bulk crystal layer structure for the construction of BN neutron detectors in which the BN semi-bulk crystals deposited on the substrate in accordance with one embodiment of the present disclosure;

FIG. 11B is an illustration of a BN semi-bulk crystal layer structure for the construction of BN neutron detectors in which the thin epitaxial-layer-templates are deposited on the substrate prior to the deposition of the final thick BN layer in accordance with one embodiment of the present disclosure;

FIG. 11C is an illustration of a BN semi-bulk crystal layer structure for the construction of BN neutron detectors in which the insertion of multiple BN thin “protection” layers are grown at lower temperatures prior to the deposition of the final thick BN layer at a higher growth temperature in accordance with one embodiment of the present disclosure;

FIG. 12 is a flow chart illustrating a method of fabricating a boron nitride (BN) layer in accordance with one embodiment of the present disclosure;

FIG. 13A-13B are a comparison of optical images of freestanding h-BN semi-bulk wafers: (a) 100% B-10 enriched h-BN (h-¹⁰BN) wafers grown by MOCVD using trimethylboron (TMB) source as a precursor; (b) A h-BN wafer of 2-inches in diameter grown by HVPE using natural boron trichloride (BCl₃) gas in accordance with one embodiment of the present disclosure;

FIG. 14 is a XRD 0-20 scan of a freestanding h-BN semi-bulk wafer grown by HVPE using BCl₃ gas as a precursor in accordance with one embodiment of the present disclosure;

FIG. 15A is a schematic of a thermal neutron detector in lateral geometry fabricated from HPVE grown h-BN with a detector strip width of W=2 mm in accordance with one embodiment of the present disclosure;

FIG. 15B is an optical image of a fabricated thermal neutron detector in lateral geometry (W=2 mm) fabricated from a 100 μm thick freestanding h-BN wafer grown by HVPE using natural boron trichloride (BCl₃) gas as a precursor in accordance with one embodiment of the present disclosure;

FIG. 15C is graph depicting the I-V characteristics of the detector shown in FIG. 15B under the illumination by a broad-spectrum UV (185 to 400 nm) light source in accordance with one embodiment of the present disclosure; and

FIG. 16 is the pulsed height spectra of the h-BN detector strip shown in FIG. 15B fabricated from a 100 μm thick freestanding h-BN wafer grown by HVPE using natural boron trichloride (BCl₃) gas as a precursor, measured at 500 V in accordance with one embodiment of the present disclosure.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity but include the general class of which a specific example may be used for illustration. The terminology herein is used to describe specific embodiments of the invention, but their usage does not limit the invention, except as outlined in the claims.

Various methods are described below to provide an example of each claimed embodiment. They do not limit any claimed embodiment. Any claimed embodiment may cover methods that are different from those described above and below. The drawings and descriptions are for illustrative, rather than restrictive, purposes.

### Physics Principle of BN Neutron Detector

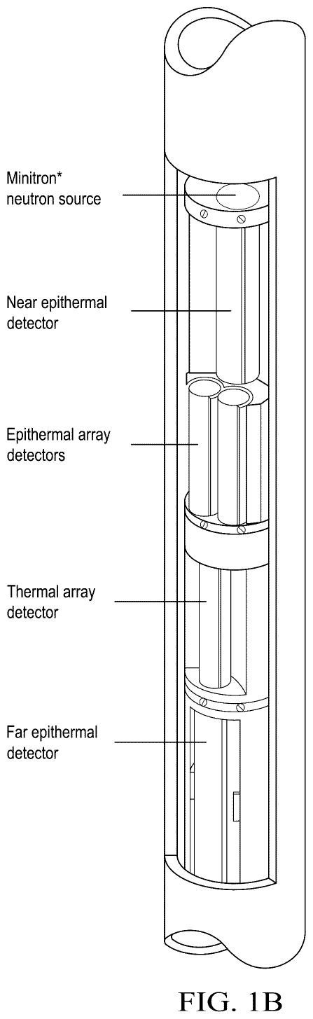

FIG. 2A plots the neutron energy dependence of the nuclear interaction probabilities between neutrons and ³He (line 202), ⁶Li (line 204) and ¹⁰B (line 206) elements (or the neutron capture cross-sections of isotopes ³He, ⁶Li and ¹⁰B), which shows that the capture cross sections of these elements are in the order of 0.4 barns for neutrons with energies between 1 to 10 MeV. FIG. 2B shows plots of the dominant elastic scattering cross-sections of fast neutrons in BN in the energy range between 0.5 and 20 MeV for ¹⁰B, ¹¹B, and ¹⁴N, which are around 1.3 Barns on average. The elastic scattering is thus a dominant process in this energy range. Using a cross-section value (dominated by elastic scattering) of fast neutrons in this energy range of around 1.3 Barns and the B and N atomic densities in B-10 enriched hexagonal BN [N(¹⁰B)=N(¹⁴N)=5.5×10²²/cm³], the macroscopic cross-section for fast neutrons in BN (h-BN) can be estimated as

$$α = N σ = 5.5 \times 1 {0}^{22} \times 2 \times 1.3 \times 1 {0}^{- 24} = 0.1 \; 43 {cm}^{- 1} \qquad ( 1 )$$

which yields a mean free path of

$$λ = {α}^{- 1} = 7 cm . \qquad ( 2 )$$

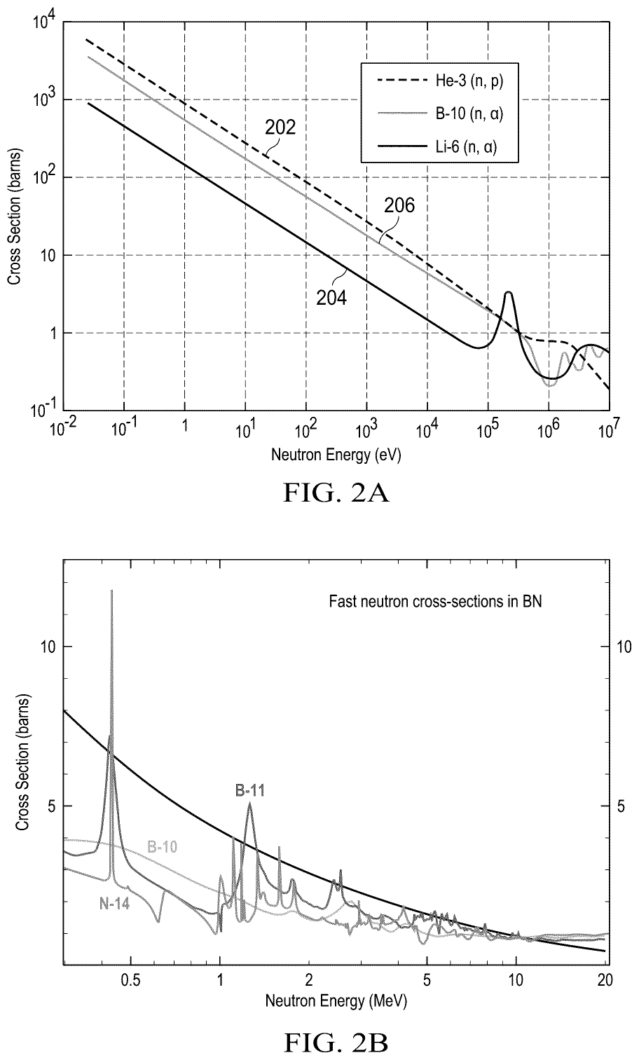

The mean free path of fast neutrons in h-BN can also be estimated experimentally to compare with the prediction result of Eq. (2) and to provide insights on the film thickness required for the construction of BN neutron detector with a reasonable detection efficiency for fast neutrons. The transmissions of fast neutrons from a Cf-252 source without high-density polyethylene (HDPE) moderator transmit through pyrolytic BN (p-BN) films have been measured. Pyrolytic BN films have a similar structural property as hexagonal BN semiconductors, except that they don't possess the necessary electronic properties to collect the charge carriers generated in the films as the BN semiconductors do. The relative neutron fluxes passing through pyrolytic BN (p-BN) films of different thicknesses (d) were measured using a BN neutron detector and the measurement results are shown in FIG. 3. It was observed that the transmission of fast neutrons in p-BN follows the relation of

$$T ∼ {e}^{- d / λ} \qquad ( 3 )$$

where d is the p-BN film thickness and k is the mean free path of fast neutrons emitted from Cf-252 neutron source. The fitting between the measured data and Eq. (3), shown in FIG. 3, yielded a value of the mean free path of λ≈7.6 cm, which agrees reasonably well with the expected value of 7 cm estimated from the cross-section of fast neutrons and atomic density of B and N atoms in h-BN semiconductors of Eq. (2). Note that the measured mean free path of λ≈7.6 cm for fast neutrons is (a) averaged over the energy range of Cf-252 source, which covers from 0.5 to 9 MeV; (b) averaged over B-10, B-11, and N-14 atoms in p-BN; (c) averaged over different scattering angles of elastic scattering between incoming fast neutrons and B and N atoms; (d) including neutron absorption, inelastic scattering, and elastic scattering processes, whereas elastic scattering is the dominant process in this energy range as shown in FIGS. 2A-2B; and (e) the p-BN films used for the transmission measurements have a similar structural property as hexagonal BN films except that p-BN films lack the ability for charge carrier collection.

Based on the experimental results of FIG. 3, the layer thickness (d) dependence of the intrinsic efficiency of BN detector for fast neutrons in the energy range between 1 to 10 MeV can be determined by using the following equation,

$$p ( d ) = ( 1 - {e}^{- d / λ} ) . \qquad ( 4 )$$

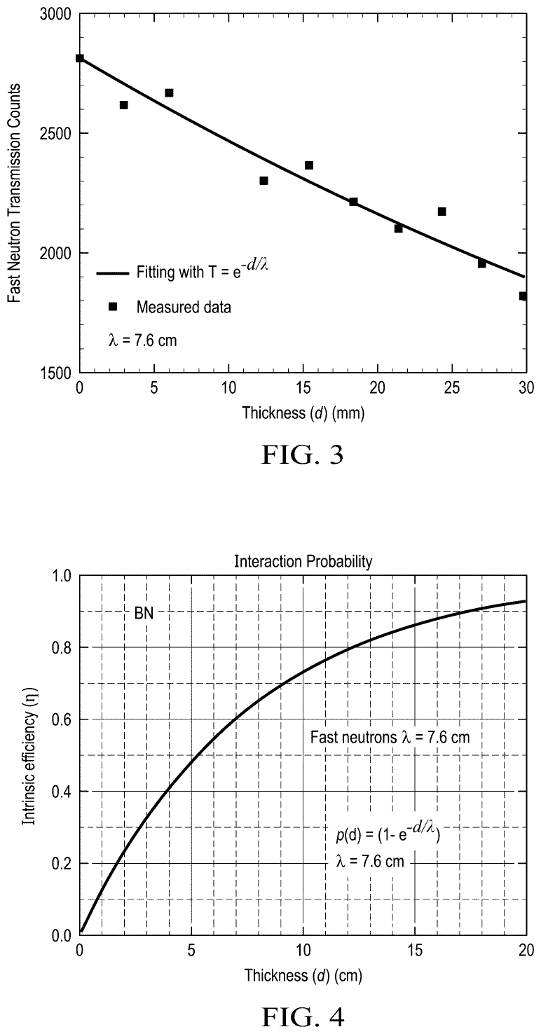

Here λ≈7.6 cm is used based on experimental results of FIG. 3. Equation 4 is plotted in FIG. 4, which clearly demonstrates that a thickness of several centimeters is required to obtain highly efficient BN detectors for detecting fast neutrons.

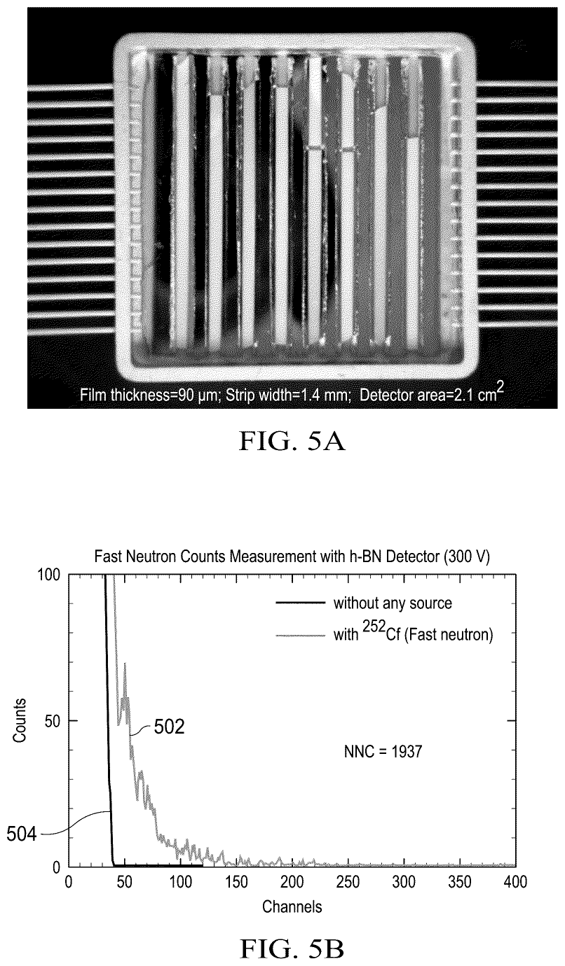

The detection of fast neutrons by a BN detector has been demonstrated. In this feasibility study case, a Cf-252 source without a HDPE moderator was used as a neutron source, which covers the energy range from E_{N}=1 to E_{N}=9 MeV. A BN detector with a detection area of 2.1 cm² fabricated from a 90 μm thick film, as shown in FIG. 5A, was used to detect the fast neutrons. FIG. 5B shows the pulsed height spectra obtained with (line 502) and without (line 504) the Cf-252 neutron source under a bias voltage of 300 V. Based on the known neutron flux and measured count rate, a detection efficiency for fast neutrons from the ²⁵²Cf source is estimated to be 0.1% for a BN detector of 100 μm in thickness. This measured result roughly agrees with the expected value deduced from Eq. (4), validating the physics principle of the detector disclosed here.

While the highest interaction probability of fast neutrons (above 1 MeV) with matters is via elastic scattering, the BN neutron detectors disclosed here are sensitive to thermal, epithermal, and fast neutrons. This is because B-10 has a very large capture cross section of 3840 barns (=3.84×10⁻²¹ cm²) for thermal neutron (E_{N}=0.025 eV) and reasonably large capture cross sections for epithermal neutrons (0.4 eV<E_{N}<1 KeV), as shown in FIG. 2A. Moreover, the detection of thermal neutrons by BN semiconductor detectors has already been demonstrated [26-34]. The principle of BN detector for detecting fast neutrons is based on detecting the charge carriers generated by recoil B and N ions in BN upon elastic scattering by incoming fast neutrons. After elastic scattering of fast neutrons with B or N atoms, the energy transferred from the fast neutrons to the recoil B or N ions will generate charge carriers. The collection of these charge carriers signifies the detection of fast neutrons as well as the energy of the recoil atom, E_{R}, as described by.

$${E}_{R} = [ 4 A / {( 1 + A )}^{2} ] ( {Cos}^{2} {θ}_{s} ) {E}_{N} , \qquad ( 5 )$$

where A is the atomic number and A=10 for B-10 atoms, A=11 for B-11 atoms, and A=14 for N-14 atoms in BN. θs is the scattering angle and E_{N} is the neutron energy. The recoil energy E_{R} decreases with an increase of the atomic weight A. Both boron and nitrogen atoms possess lowest atomic numbers among all semiconductors, which provides an important advantage for BN as a fast neutron detection material in comparison with other semiconductors. A larger E_{R} value naturally translates to a larger number of charge carrier generation in BN and so a higher detection efficiency. The total number of free electrons (Nₑ) and holes (Nₕ), where Nₑ=Nₕ, generated from recoil energy E_{R} can be written as

$${N}_{e} = {N}_{h} = {E}_{R} / 3 {E}_{g} , \qquad ( 6 )$$

where E_{g} is the energy band gap of BN (≈6 eV).

### Detailed Design of BN Detector

The present disclosure relates to the design and fabrication of semiconductor neutron detectors for energies up to tens of mega-electron volts (MeV) based on boron nitride (BN) wide bandgap semiconductor semi-bulk crystals. The neutron detector includes one or more boron nitride (BN) strips electrically connected in parallel or series. Guided by the result shown in FIG. 4 as well as by Eq. (4), the required thickness of BN for attaining a practical detection efficiency for fast neutrons is several centimeters (cm). However, it is not feasible to grow hexagonal BN films with a few cm in thickness. Even if one can grow BN films with a few cm in thickness, it is not practical to supply a sufficient electric field on the order of 10³ to 10⁴ V/cm needed for charge collection. Therefore, various embodiments of the disclosed BN detector are constructed by stacking up multiple blocks of BN films or depositing them on a substrate with a gap between the BN films, all of which are about 1 mm in thickness with a sufficient detection area. With this design, a bias voltage of V≥100 V can supply an electric field of E≥10³ V/cm to provide a sufficient detection efficiency and sensitive for fast neutrons.

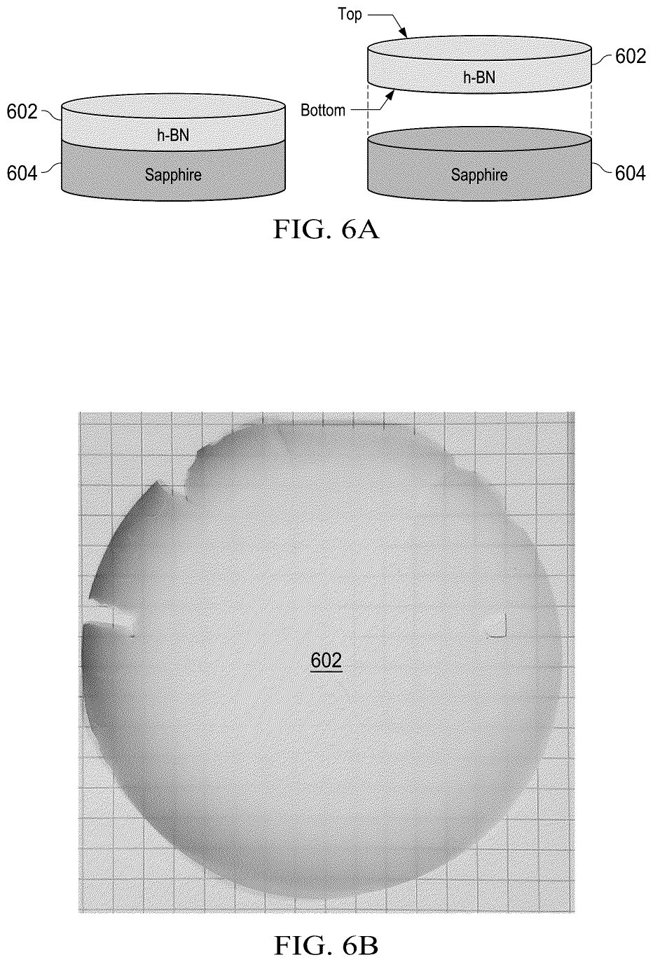

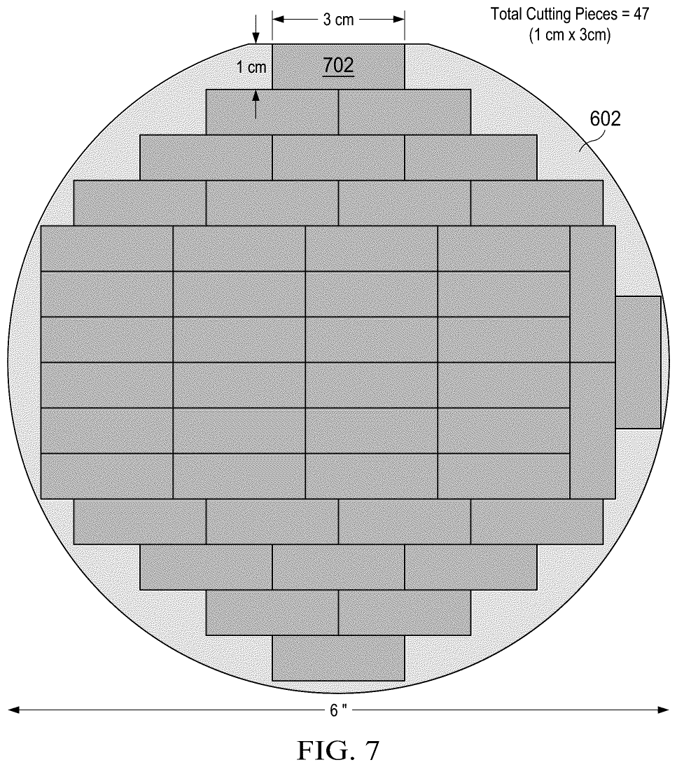

To obtain the growth of BN with a thickness of about 1 mm, a fast growth rate is needed. BN semi-bulk crystals with a thickness of 1 mm shall be grown by film growth techniques which offer fast growth rates. These include hydride vapor phase epitaxy (HVPE), sputtering, pulsed laser deposition (PLD), chemical vapor deposition (CVD), metal organic vapor deposition (MOCVD), etc. Due to the different thermal expansion coefficients between hexagonal BN (h-BN) and sapphire, h-BN layers 602 will be naturally separated from the sapphire substrates 604 and a thick free-standing h-BN 602 can be obtained, as shown in FIGS. 6A-6B. These free-standing h-BN layers 602 can be cut by laser dicing or mechanical dicing into desired shapes and number of blocks according to the detector design. FIG. 7 illustrates a dicing scheme for a wafer of 6-inches in diameter, from which a total of 47 BN blocks 702 each with an area of 1 cm×3 cm can be realized. These BN blocks 702 can be used to construct the stacked fast neutron detectors disclosed below.

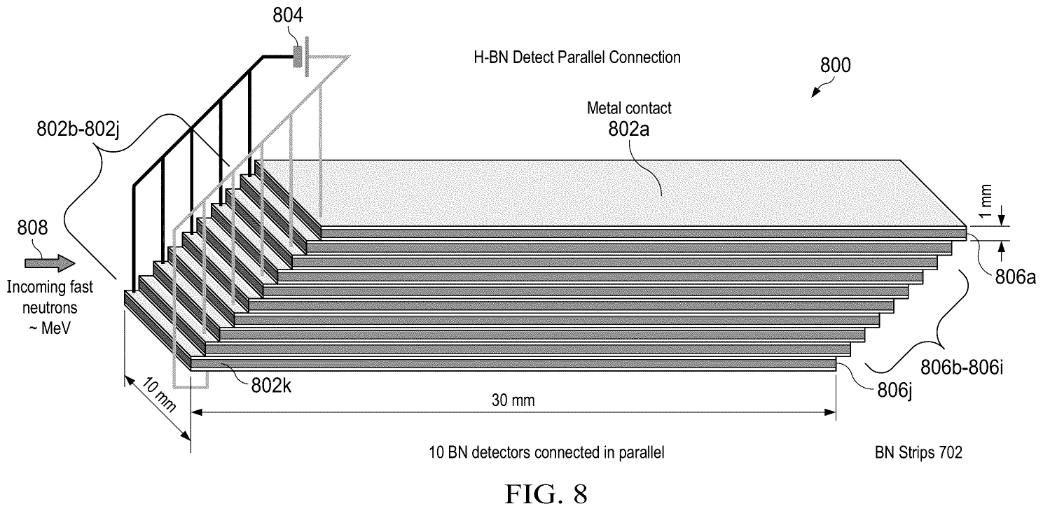

FIG. 8 shows a detailed design of the vertical transport neutron detector in accordance with one embodiment of the disclosure. As shown in FIG. 8, 10 blocks of BN 702 will be stacked up to form a neutron detector 800 with a total dimension of 1 cm×1 cm×3 cm, which is sensitive to neutrons with energies ranging from thermal to fast neutrons. Metal contacts 802-k are disposed on the top of the neutron detector 800, the bottom of the neutron detector 800 and in between each block of BN 702. The blocks 702 are then connected in parallel as illustrated by lines 804. Following the elastic scattering of fast neutrons with B or N atoms, the energy transferred from fast neutrons to the recoil B or N ions will generate charge carriers and the collection of these charge carriers signals the detection of incoming fast neutrons.

To compensate for the small cross-section of fast neutrons in the energy range up to tens of MeV, the detector 800 is designed to have a long path length of 3 cm for the incoming fast neutrons and a cross-section area of 1 cm×1 cm. The use of a long path length of the detector (3 cm) is to ensure that the detector will provide a sufficient detection efficiency for fast neutrons in the energy range up to tens of MeV. Since the measured mean free path of fast neutrons in BN shown in FIG. 3 is about 7.6 cm, if the incoming neutrons are traveling along the direction of long axis with a path length of L=3 cm, the intrinsic detection efficiency will be 1-exp (−L/λ)=1-exp (−3 cm/7.6 cm)=33%. If the incoming neutrons are traveling along the direction of short axis of 1 cm in length, the intrinsic detection efficiency will be 1-exp (−1 cm/7.6 cm)=12%. Hence, the overall intrinsic detection efficiency of BN for fast neutrons will be between 12% and 33% if incoming neutrons are traveling along a random direction. Considering the possibility that the amount of energy transferred from fast neutrons via elastic scattering events with larger scattering angles may not be large enough to generate a density of electron and hole pairs which is detectable, BN neutron detectors can still reach an overall efficiency of greater than 8% for fast neutrons.

Accordingly, one embodiment of the present disclosure provides a neutron detector 800 that includes two or more boron nitride (BN) strips 806a-806j stacked on one another and electrically connected in parallel 804 or series to support a charge transport in a lateral direction as indicated by arrow 808 with respect to the BN strips 806a-806j.

In one aspect, the BN strips 806a-806j are laterally offset from one another. In another aspect, the BN strip 806a-806j has a width (W) of about 1 to 10 mm, a length (L) of about 10 to 50 mm, and a thickness (c) or height (H) of about 0.1 mm to 10 mm thick. In another aspect, the BN strips 806a-806j comprise Boron-10 enriched hexagonal boron nitride or natural BN crystals. In another aspect, the BN strips 806a-806j comprise 1, 2, 3, 4, 5, 6, 7, 8, 9, 10, 11, 12 or more intermediate BN strips. In another aspect, a housing encloses the BN strips 806a-806j. In another aspect, a gamma-ray shield is disposed around the housing. In another aspect, the neutron detector further includes: metal contacts 802a-802j are disposed on a top and a bottom of the BN strips 806a-806j; and two or more BN strips 806a-806j are stacked on one another and connected together through the metal contacts 802a-802j in parallel (see connections 804) or series to support a charge transport in a vertical direction with respect to planes of the two or more BN strips 806a-806j.

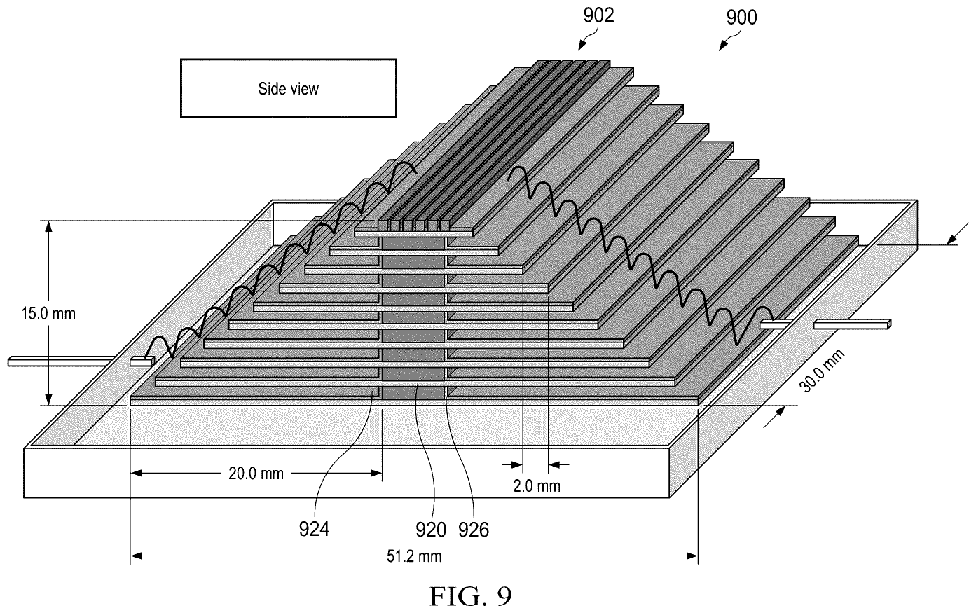

FIG. 9 shows the detailed design for a lateral transport neutron detector in accordance with one embodiment of the disclosure. In another aspect and as illustrated in FIG. 9, the neutron detector further includes: an intermediate substrate disposed in between each of the two or more BN strips; a first metal contact disposed on a first longitudinal side of each of the two or more BN strips; a second metal contact disposed on a second longitudinal side of each of the two or more BN strips; and wherein the first metal contacts and second metal contacts are used to electrically connect the two or more BN strips in parallel to support a charge transport in a lateral direction with respect to planes of the two or more BN strips. In another aspect, each intermediate substrate and the lower substrate comprise sapphire, pyrolytic BN, free-standing hexagonal BN, SiC, or polycrystalline diamond. In another aspect, the lower substrate is larger than each intermediate substrate, and the intermediate substrates become progressively smaller from the lower substrate to the upper BN strip. In another aspect, one or more buffer layers are disposed on top of the lower substrate and each intermediate substrate. In another aspect, one or more epitaxial layer templates are disposed on top of each of the one or more buffer layers. In another aspect, the one or more epitaxial layer templates comprise AlN, BN, GaN or diamond materials.

Another embodiment of the present disclosure provides a method for detecting neutrons using the neutron detector described above.

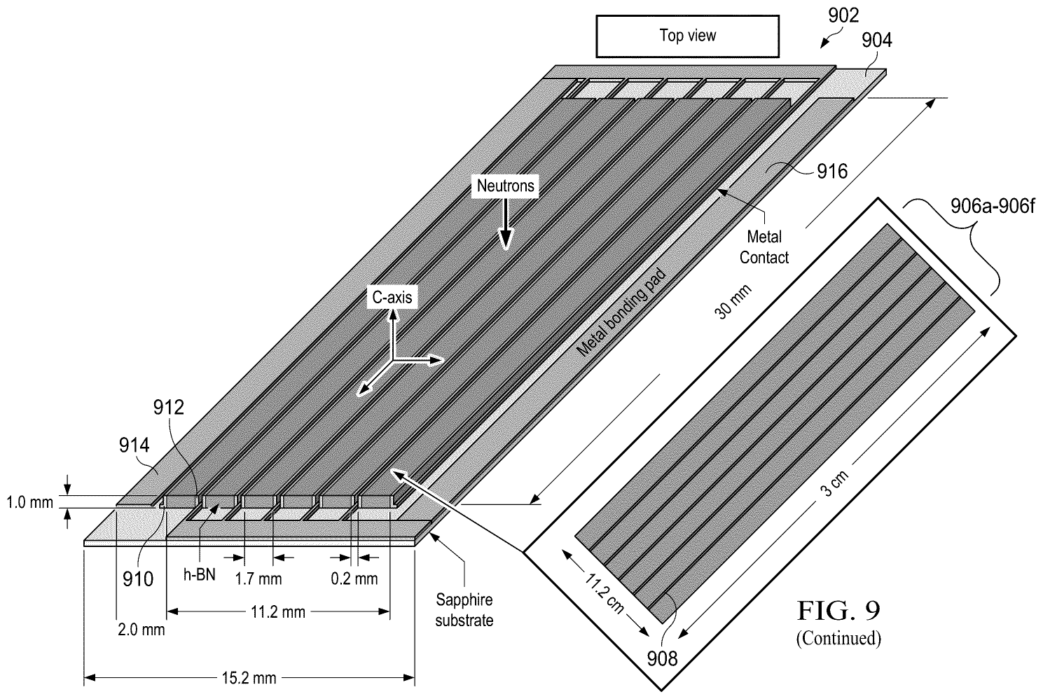

In one aspect, the detected neutrons comprise thermal to fast neutrons. In another aspect and as shown in FIG. 10B, the fast neutrons are converted to thermal neutrons by adding a block of HDPE material 1002 around the neutron detector 1004. In another aspect, it is determined whether a neutron source comprises a thermal neutron source or a fast neutron source based on a change in a counting rate of the thermal neutrons after adding the block of HDPE material 1002.

Due to the layered structure, the lateral transport properties of hexagonal BN are superior to those in the vertical direction [29]. Stacked detector with the charge transport occurring in the lateral direction can also be constructed to take the advantage of the exceptional lateral transport properties of hexagonal BN, as illustrated in FIG. 9. The detector 900 is also constructed by stacking up a total of 10 blocks (or more) of h-BN with a dimension of 1 cm×1 cm×3 cm or larger. However, in comparison to the vertical detector geometry shown in FIG. 8, the bias voltage is applied in the direction of BN layer plane. Therefore, the charge transport and charge carrier collection take place in the lateral direction. As demonstrated for thermal neutron detectors [26-28], the main benefits of utilizing the lateral transport include that the in-plane mobilities of electrons and holes are much higher than those of out-plane and the surface recombination velocities are significantly reduced [28-31]. Therefore, the lateral detector should provide a higher detection efficiency. To supply a sufficient electric field for charge collection, each BN block is further diced into narrow strips of 1-2 mm in width and then these multiple strips are connected in parallel. FIG. 9 provides one example with a strip width of 1.7 mm. The 10 BN blocks in the vertical direction will also be connected in parallel. The choice of 1-2 mm strip width is based on the results obtained from thermal neutron detectors with high detection efficiencies [26-28]. The lateral detector shown in FIG. 9 has 10 blocks of BN stacked up with an equivalent dimension of 1 cm×1 cm×3 cm. Hence, the intrinsic efficiency of the vertical and lateral charge transport detectors shown in FIGS. 8 and 9 should be similar. In practice, however, the lateral charge transport detector is expected to possess a higher charge collection efficiency because the electron and hole mobilities are higher in the lateral direction, which will result in an improved detection efficiency. It has been shown that BN thermal neutron detectors are inherently insensitive to gamma rays due to the small atomic numbers of B and N [26-28]. To further ensure no interference from gamma photons, a layer of gamma-ray shield (Tungsten, Bismuth, Lead etc.) can be added around the detector housing to further eliminate the response of the detector to gamma rays.

Another embodiment of the present disclosure provides a neutron detector 902 that includes a substrate 904, one or more boron nitride (BN) strips (e.g., 906a-906f) disposed on the substrate 904 with a gap 908 between the two or more BN strips (e.g., 906a-906f), a first metal contact 910 disposed on a first longitudinal side of each of the two or more BN strips (e.g., 906a-906f), and a second metal contact 912 disposed on a second longitudinal side of each of the two or more BN strips (e.g., 906a-906f). The first metal contacts 910 and second metal contacts 912 are used to electrically connect the two or more BN strips (e.g., 906a-906f) in parallel, and a charge transport is supported in a vertical direction with respect to the two or more BN strips (e.g., 906a-906f).

In one aspect, the gap 908 comprises 0.1 to 2 mm. In another aspect, a housing encloses the two or more BN strips (e.g., 906a-906f). In another aspect, a gamma-ray shield is disposed around the housing. In another aspect, the neutron detector 900 further includes: the substrate 906 comprises a first substrate having a first metal pad 914 connected to the first metal contacts 910 and a second metal pad 916 connected to the second metal contacts 912; the two or more BN stripes (e.g., 906a-906f) comprise two or more first BN strips; one or more BN assemblies (e.g., 918a-918i) disposed below the first substrate 906, each of the one or more BN assemblies (e.g., 918a-918i) comprise: a second BN strip 920, a second substrate 922 disposed below the second BN strip 920, a third metal contact 924 disposed on a first longitudinal side of the second BN strip 920, and a fourth metal contact 926 disposed on a second longitudinal side of the second BN strip 920; and the first metal pad 914, the second metal pad 916, the third metal contacts 924, the fourth metal contacts 926 are used to electrically connect the two or more first BN strips (e.g., 906a-906f) and each second BN strip 920 in parallel. In another aspect, the first substrate 906 and the second substrate (e.g., 918a-918i) comprise sapphire, pyrolytic BN, free-standing hexagonal BN, SiC, or polycrystalline diamond. In another aspect, the first substrate 906 is smaller than each second substrate (e.g., 918a-918i), and the second substrates become progressively larger from the first substrate to a bottom of the second substrates. In another aspect, one or more buffer layers are disposed on top of the first substrate and the second substrate. In another aspect, one or more epitaxial layer templates are disposed on top of each of the one or more buffer layers. In another aspect, the one or more epitaxial layer templates comprise AlN, BN, GaN or diamond materials.

Another embodiment of the present disclosure provides a method for detecting neutrons using the neutron detector described above.

In one aspect, the detected neutrons comprise thermal to fast neutrons. In another aspect and as shown in FIG. 10B, the fast neutrons are converted to thermal neutrons by adding a block of HDPE material 1002 around the neutron detector 1004. In another aspect, it is determined whether a neutron source comprises a thermal neutron source or a fast neutron source based on a change in a counting rate of the thermal neutrons after adding the block of HDPE material 1002.

In contrast to BN thermal neutron detectors, which are made from B-10 isotope enriched BN films [26-28], natural BN crystals can be used to construct the BN neutron detectors disclosed here. Natural BN crystals can be grown by film growth techniques, including but not limited to hydride vapor phase epitaxy (HVPE), sputtering, pulsed laser deposition (PLD), chemical vapor deposition (CVD), metal organic vapor deposition (MOCVD), etc. using natural boron sources. Natural boron sources contain 20% of B-10 and 80% of B-11. The use of natural B source will bring down significantly the raw material cost compared to the use of ¹⁰B isotope enriched B sources. For thermal neutron detection, the nuclear interaction probability (or cross-section) of B-11 with thermal neutron can be neglected. This renders a mean free path (or absorption length) of thermal neutrons in natural hexagonal BN (h-BN) crystal of 235 μm (5 times longer than a value of 47 μm in B-10 enriched h-BN) [26]. Based on the designs shown in FIGS. 8 and 9, the total neutron path lengths in the detectors are several orders of magnitude larger than 235 μm in all 3 dimensions. As such, the intrinsic detection efficiency of the disclosed detector for thermal neutrons is almost 100% even with the use of natural h-BN. The intrinsic detection efficiency of the disclosed detector for epithermal neutrons will also be high because of the relatively large nuclear interaction probabilities (or cross-sections) of ¹⁰B element with epithermal neutrons, providing an absorption length of up to a few mm, which are much smaller than the total neutron path lengths in all 3 dimensions of the detectors disclosed, which are all exceeding 10 mm. Moreover, for fast neutron detection, as shown in FIG. 2B, the elastic scattering cross-sections of B-10 and B-11 in the energy range of 1 to 10 MeV are very comparable. Therefore, the neutron detectors disclosed here have a comparable efficiency regardless weather they are constructed from natural BN or from B-10 enriched BN. The use of natural BN crystals will significantly reduce the production cost of BN fast neutron detectors.

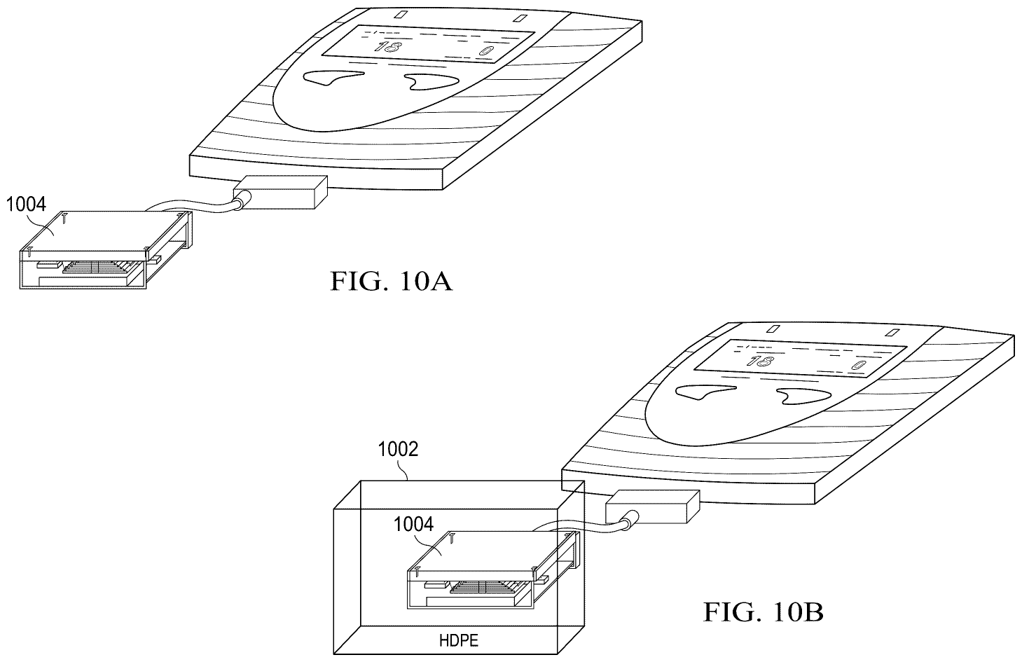

As illustrated in FIG. 11A, to grow BN semi-bulk crystals or thick films 1102 with a thickness of around 1 mm, a substrate 1004 such as sapphire (Al₂O₃) is be used. Other suitable substrates 1102 for the growth of thick BN film include pyrolytic BN, free-standing h-BN, SiC, and polycrystalline diamond. One or more buffer layers 1106 can be disposed between the BN semi-bulk crystals or thick films 1102 and the substrate 1104. Other thin epitaxial layer templates 1108 deposited on substrate 1104 can be used to reduce the diffusion of impurities from the substrate if sapphire or SiC are used as substrates, as illustrated in FIG. JIB, as oxygen and carbon related impurities and defects are shown to be as unfavorable in BN detectors [30, 31]. These epi-templates 1108 include AlN, BN, GaN, diamond materials. Moreover, insertion of multiple BN thin “protection” layers of hundreds of nanometers to tens of microns in thickness grown at lower temperatures of 800-1300° C., which typically are amorphous thin films, prior to the deposition of the final thick BN layer grown at higher temperatures of typically greater than 1400° C. not only reduces the diffusion of impurities from the substrate, but also mitigates the issues induced by lattice mismatch between the thick BN layer 1102 and the substrate 1104. BN semi-bulk crystals can be grown by film growth techniques, including but not limited to, hydride vapor phase epitaxy (HVPE), sputtering, pulsed laser deposition (PLD), chemical vapor deposition (CVD), metal organic vapor deposition (MOCVD), etc. using natural boron sources.

FIG. 11C is an illustration of a BN semi-bulk crystal layer structure for the construction of BN neutron detectors in which the insertion of multiple BN thin “protection” layers are grown at lower temperatures prior to the deposition of the final thick BN layer at a higher growth temperature in accordance with one embodiment of the present disclosure.

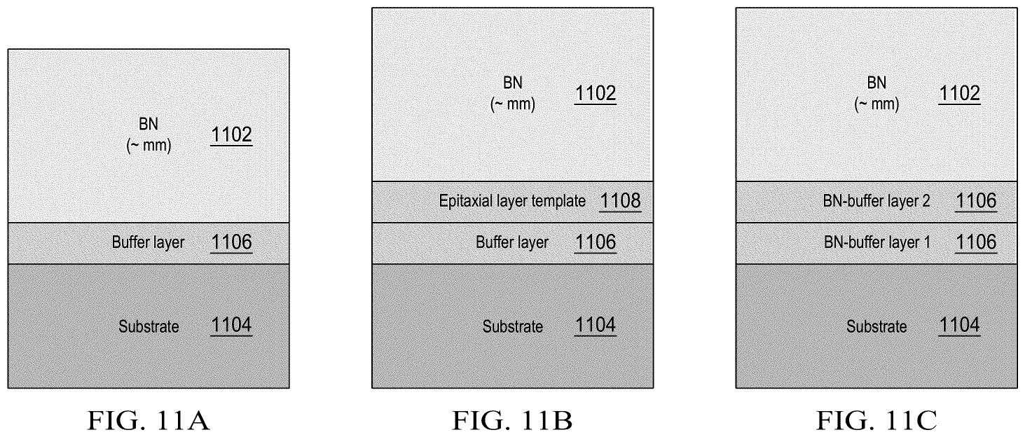

As shown in FIG. 12, another embodiment of the present disclosure provides a method 1200 of fabricating a boron nitride (BN) layer 1102 by depositing one or more buffer layers 1106 on a substrate 1104 in block 1202, and growing the BN layer 1102 on the one or more buffer layers 1106 in block 1204.

In one aspect, the substrate 1104 comprises sapphire, pyrolytic BN, free-standing hexagonal BN, SiC, or polycrystalline diamond. In another aspect, the BN layer 1102 comprises Boron-10 enriched hexagonal boron nitride or natural BN crystals. In another aspect a thickness of the BN layer 1102 comprises 0.1 to 3 mm. In another aspect, the BN layer 1102 is grown using hydride vapor phase epitaxy (HVPE), sputtering, pulsed laser deposition (PLD), chemical vapor deposition (CVD), or metal organic vapor deposition (MOCVD). In another aspect, one or more epitaxial layer templates 1108 are deposited on top of the one or more buffer layers 1106 prior to growing the BN layer 1102 in block 1206. In another aspect, the one or more epitaxial layer templates 1106 comprise AlN, BN, GaN or diamond materials.

In terms of operating lifetime of BN detectors, in the absence of any radiation, the variation of BN detector performance with time can be neglected because of the inherent stability of h-BN material itself in the air. The durability of h-BN detectors under neutron irradiation can be assessed. Under neutron irradiation, B and N atoms will be displaced after each elastic scattering, a process which ends up generating two defects, one vacancy and one interstitial in BN. By applying the general rule of thumb in semiconductors, the performance of a semiconductor device would not be affected by the presence of impurities/defects if the impurity/defect concentration is below 10¹³/cm³, whereas the typical impurity concentration needed to control the conductivity of a semiconductor has to be greater than 10¹⁶ cm⁻³ If a total count of 10³ is needed to confirm a detection signal and charge collection efficiency is 20%, the number of defects generated from each detection will be 10⁴. The total volume of the detector is 1 cm×1 cm×3 cm=3 cm³, from which the density of defects created in the detector can be estimated to be 10^{4/3} cm³=3.3×10³ cm⁻³. If a target for 10⁸ (100 million) detection cycles during the lifetime of the detector is selected, the total density of defects generated will be 3.3×10¹¹ cm⁻³. Therefore, elastic scattering between fast neutrons and B and N atoms will not create a sufficient defect density, which otherwise would affect the performance of BN fast neutron detectors.

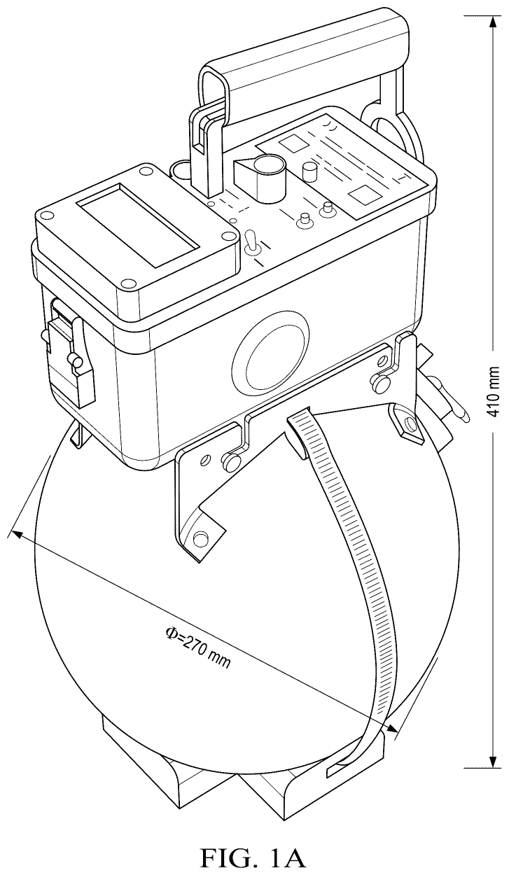

Not only the detectors disclosed here can detect simultaneously neutrons with energies ranging from those of thermal to fast neutrons, but they can also be utilized to identify the nature of unknown neutron source emitting predominantly thermal or fast neutrons. As schematically illustrated in FIGS. 10A and 10B, after detecting a neutron signal, one can determine if they are thermal or fast neutrons by adding a block of HDPE material 1002 around the BN neutron detectors 1004 disclosed here. If the counting rate increases after adding the HDPE block 1002, the unknown radiation source is most likely of a fast neutron origin since this is the principle of the current existing fast neutron detection technology, which uses an HDPE block 1002 to convert fast neutrons to thermal neutrons as shown in FIG. 1A. If the counting rate decreases after adding an HDPE block 1002, then the unknown source is more likely a thermal neutron source because a fraction of these thermal neutrons will be lost after passing through the HDPE block 1002. The thickness of this HDPE block should be around 2.5 cm with an overall dimension of slightly larger than that of the disclosed BN neutron detector.

### Cost-Effective Hexagonal BN Semi-Bulk Crystals and BN Neutron Detectors Via Halide Vapor Epitxy

Presently, thermal neutron detectors fabricated from boron-10 enriched hexagonal boron nitride (h-¹⁰BN) ultrawide bandgap semiconductor grown by metal organic chemical vapor deposition (MOCVD) hold the record high detection efficiency among all solid-state detectors at 59%. To overcome the short comings of MOCVD growth, including inherently low growth rate and unavoidable impurities such as carbon in metal organic source, it is demonstrated here that the growth of natural hexagonal boron nitride (h-BN) semi-bulk wafers using halide vapor phase epitaxy (HVPE) which is an established technique for producing GaN semi-bulk crystals at a high growth rate. Electrical transport characterization results revealed that these HVPE grown materials possess an electrical resistivity of 1×10¹³ Ω·cm, and a charge carrier mobility and lifetime product of 2×10⁻⁴ cm²/V·s. Detectors fabricated from a 100 μm thick h-BN wafer have demonstrated a thermal neutron detection efficiency of 20%, corresponding to a charge collection efficiency of ˜60% at an operating voltage of 500 V. This initial demonstration opens the door for mass producing high efficiency h-BN semiconductor neutron detectors at a reduced cost, which could create unprecedented applications in nuclear energy, national security, nuclear waste monitoring and management, the health care industry and material sciences.

The development of III-nitride wide bandgap semiconductor technology has made huge impact on society, ranging from the creation of white light to consumer electronics in an entirely new manner [35]. Among III-nitrides, hexagonal BN (h-BN) with an ultrawide bandgap (˜6.0 eV) in the three-dimensional form is the least studied in terms of material growth and device applications [36-39], although few-layer h-BN has been widely utilized as a complementary dielectric substrate and gate for 2D electronics [40-44] as well as a host for optically stable single photon emitters [45-48]. One of the distinct properties which sets BN apart from conventional III-nitrides is that the isotope B-10 (¹⁰B) is one of only few elements which possess large interaction cross sections with thermal neutron (σ), where σ=3480 Barns or 3.48×10⁻²¹ cm² for B-10 [49-50]. The density of ¹⁰B atoms in 100% B-10 enriched h-BN (h-¹⁰BN) is N(¹⁰B)=5.5×10²²/cm³, which provides a thermal neutron absorption coefficient (α) and absorption length λ of α (h-¹⁰BN)=Nσ=5.5×10²²×3.84×10⁻²¹=211.2 cm⁻¹ and, (h-¹⁰BN)=α⁻¹=47.3 μm, respectively [27-28, 31-32, 34, 51]. Since boron has two natural stable isotopes, with an average of 20% and 80% of ¹⁰B and ¹¹B in natural abundance respectively, the density of ¹⁰B atoms in natural h-BN is 5 times smaller than that in h-¹⁰BN, and therefore λ(h-BN)=237 μm.

It has been widely recognized recently by the wide bandgap semiconductor research community that h-BN is an ideal material for the realization of solid-state direct conversion thermal neutron detectors [52]. The key material parameters of h-¹⁰BN produced by metal organic chemical vapor deposition (MOCVD), including the mobility-lifetime product, layer thickness, and electrical resistivity, all have been increased by several orders of magnitude over a period of several years [27-28, 32, 34, 51]. These improvements have enabled the realization of high-performance h-¹⁰BN semiconductor thermal neutron detectors [27-28, 32, 34]. Presently, h-¹⁰BN thermal neutron detectors hold the record high detection efficiency among all solid-state detectors at 59% (for a 1 cm² detection area) [28].

Indirect-conversion semiconductor detectors via either coating a thin ⁶Li or ¹⁰B neutron conversion layer on a bulk semiconductor [11, 20, 22] or formation of micro-pillars in a bulk semiconductor filled with a ¹⁰B or ⁶Li neutron conversion material [14, 16-17, 53] have been developed, with the former being commercialized. Compared to the indirect-conversion semiconductor detectors with a limited theoretical detection efficiency, neutron absorption and charge collection occur in the same h-BN layer. The theoretical detection efficiency of h-BN thermal neutron detectors scales with the h-BN layer thickness were previously discussed in reference to Equation 4. Note that ηᵢ can approach 100% if the detector thickness is sufficiently large. So far, all high-performance neutron detectors were fabricated from h-¹⁰BN materials grown by MOCVD in authors' lab [27-28, 32, 34]. While MOCVD growth technique is well-established for producing high quality III-nitride materials, its growth rate is limited (up to several microns per hour) and is best suited for fabricating photonic and electronic device structures [35]. The large thermal neutron absorption length, λ (h-¹⁰BN)=α⁻¹=47.3 μm or λ (h-BN)=237 μm, makes the thickness requirement for the construction of high efficiency neutron detectors a great challenge for MOCVD epitaxial growth. The required long growth time translates to high cost. Additionally, the metal organic precursors used in MOCVD growth inevitably contain carbon impurities and sometimes even oxygen impurities, which are known to be deep level defects in h-BN [54] and are undesired for the performance of h-BN neutron detectors [27-28, 31-32, 34].

Halide vapor phase epitaxy (HVPE) growth is an established technique for producing semi-bulk GaN crystals in large wafer size at a high growth rate. More recently, HVPE growth technique has been employed to produce GaN vertical p-n junction devices with a significantly improved p-type conductivity control through the elimination of the residue carbon impurities [55-56]. HVPE growth of natural h-BN is reported herein. The detector fabricated from a 100 μm thick h-BN wafer delivered an overall detection efficiency of n=20%, corresponding to a charge collection efficiency of ˜60%. This initial demonstration opens the feasibility for producing cost-effective h-BN semi-bulk crystals and high efficiency h-BN semiconductor neutron detectors via HVPE.

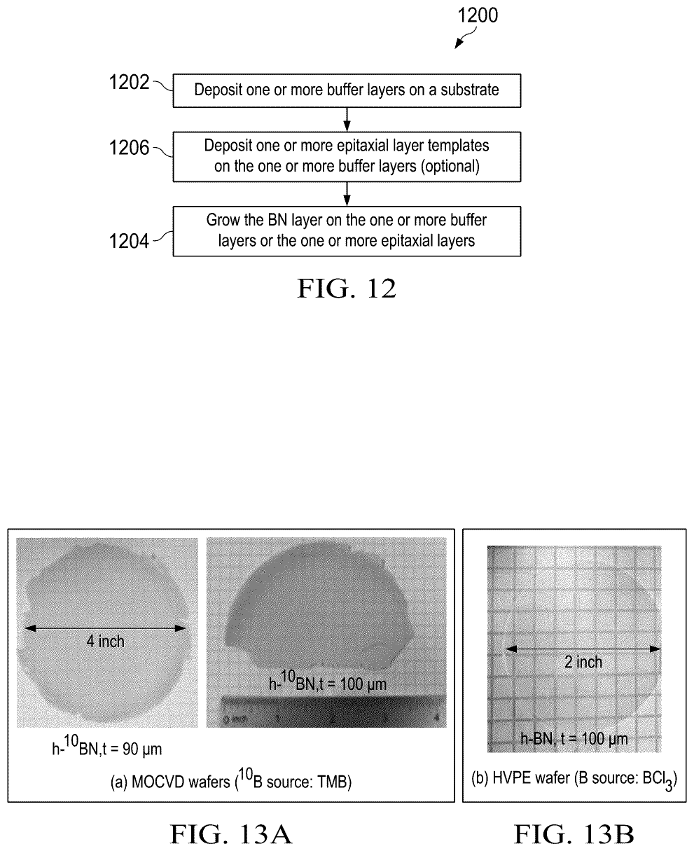

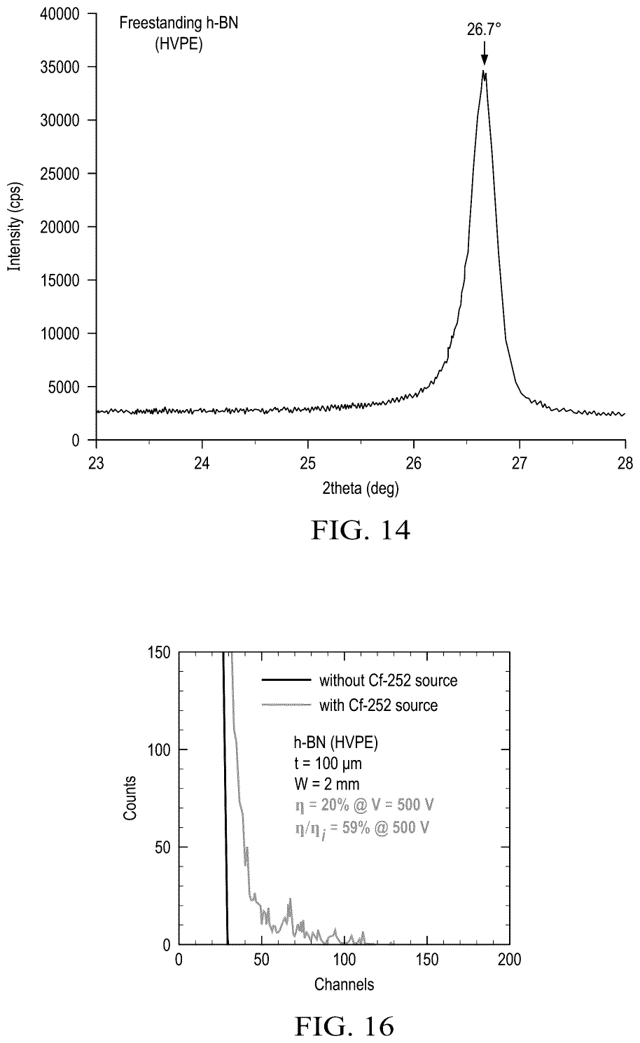

To grow h-BN wafers, natural boron trichloride (BCl₃) and NH₃ were used as precursors. The growth was conducted on c-plane sapphire of 2-inches in diameter at a growth rate of about 25 μm/h. Due to its layered structure, after growth during cooling down, h-BN self-separates from sapphire to form a freestanding wafer [27-28, 32, 34]. FIGS. 13A-13B compare optical images among representative wafers (a) grown by MOCVD using B-10 enriched trimethylboron (TMB) metal organic (MO) source as a precursor [27-28] and (b) grown by HVPE in the present work. As can be seen from this side-by-side comparison, h-BN wafer grown by HVPE using BCl₃ gas as a precursor exhibits a much better transparency and less yellowish color than those produced by MOCVD using TMB source. The improved transparency is related to the fact that the BCl₃ precursor contains no carbon impurities. A previous theoretical work indicates that carbon impurities in h-BN can occupy both B and N sites as well on an interstitial site [54]. When occupying B site, CB is a deep donor with an energy level of 2.2 eV below the conduction band edge and when occupying an interstitial site, Cᵢ is a deep acceptor sitting at an energy level of 2.4 eV above the valence band edge [54], and the presence of both of which will render a yellowish colored wafer. When occupied on N site, C_{N} is an extremely deep level acceptor with a transition energy of 3.2 eV to the valence band [54]. FIG. 14 shows the x-ray diffraction (XRD) θ-2θ scan, revealing a dominant diffraction peak at 26.7°, corresponding to a c-lattice constant of 6.67 Å, associated with the hexagonal phase of BN. The XRD spectral line shape is quite comparable to those of MOCVD grown h-¹⁰BN semi-bulk wafers reported earlier by our group [56]. In terms of optical properties, the room temperature photoluminescence emission spectra of HVPE semi-bulk wafers exhibit peaks associated with both the band-edge and impurity transitions, while MOCVD grown semi-bulk crystals (>30 μm) exhibit only transitions related to the deep level defects [31, see e.g., FIG. 20].

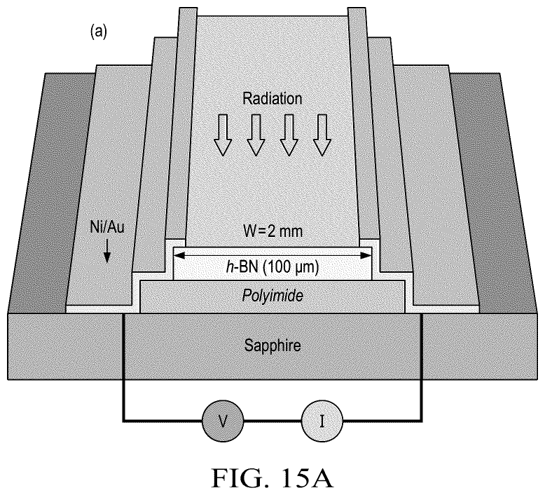

For the electrical property and neutron detection performance studies, lateral detectors were fabricated to take the advantages of h-BN's superior lateral transport properties over its vertical transport properties [31]. The fabrication processes include the following steps: (1) dicing h-BN wafer into detector strips, (2) mount detector strips on sapphire using a highly resistive adhesive material; and (3) a mask was used to deposit metal contacts consisting of a bi-layer of Ni (100 nm)/Au (40 nm) on the clipped edges of the h-BN strips using e-beam evaporation, leaving around ˜100 μm of metal covering on the two edges [27-28]. The schematic illustration of these lateral detectors is depicted in FIG. 15A. FIG. 15B shows a micrograph of a fabricated detector strip (2 mm in width) mounted on sapphire via a layer of highly resistive and adhesive polyimide. Dark I-V characterization yields an electrical resistivity of 1.1×10¹³ Ω·cm, which is comparable to those of MOCVD grown h-¹⁰BN [27-28, 32, 34].

One of the most important parameters for determining the charge collection efficiency of a neutron detector is its carrier mobility and lifetime product (μτ) [27-28, 31, 32, 34, 57]. Most of the neutron-generated charge carriers inside a detector can be collected when the carrier recombination time (τ) is greater than the transit time (τₜ), τ>τₜ, or equivalently the charge carrier drift length (=μτE) is greater than the carrier transit distance (or the width of the detector strip, W). This mean that μτE>W is the condition to ensure a high charge collection efficiency, where W is the width of the detector strip and E (V) is the applied electric field (bias voltage). The quantity of μτ is strongly influenced by the overall material quality. For MOCVD grown h-¹⁰BN, the pi values measured under UV excitation have been improved by several orders of magnitude from 10⁻⁸ cm²/V [57] to 5×10⁻³ cm²/V [28], leading to the realization of high-performance neutron detectors [28]. Since the growth of HVPE of h-BN is at an initial stage, it is desirable to benchmarking the μτ parameter against those of MOCVD grown materials. The photocurrent-voltage (I-V) characteristics under UV excitation was utilized to extract μτ value using the classical Many's equation for insulating semiconductors [58]. Since the contact area is small in a lateral detector, the effect of surface recombination was neglected and only the bulk trapping effect was taken into consideration, which yields an expression for the I-V characteristics under illumination as

$$I ( V ) = {I}_{o} [ \frac{{μ}_{n} {τ}_{n} V}{{W}^{2}} - {( \frac{{μ}_{n} {τ}_{n} V}{{W}^{2}} )}^{2} ( 1 - {e}^{- \frac{W}{{μ}_{n} {τ}_{n} V}} ) + \frac{{μ}_{p} {τ}_{p} V}{{W}^{2}} - {( \frac{{μ}_{p} {τ}_{p} V}{{W}^{2}} )}^{2} ( 1 - {e}^{- \frac{{W}^{2}}{{μ}_{p} {τ}_{p} V}} ) ] . \qquad ( 7 )$$

The measured I-V characteristics under the illumination by a broad-spectrum UV (185 to 400 nm) light source is shown in FIG. 15C. In fitting the data with Equation 7, it was assumed that the μτ product for electrons and holes are comparable (μₙτₙ=μₚτₚ) in the lateral direction [31] for initial assessment. The fitting results provided a μτ value of 2×10⁻⁴ cm²/V, which is on the same order as the values of most MOCVD grown semi-bulk wafers [27, 31-32, 34] and is sufficiently large to satisfy the charge collection condition of μτE>W if the detector is operated at the same bias voltage of 500 V as in the previous best performing h-¹⁰BN detector [28]. The μτ products can be measured under an alpha source irradiation, which resembles more closely to the scenario of thermal neutron irradiation.

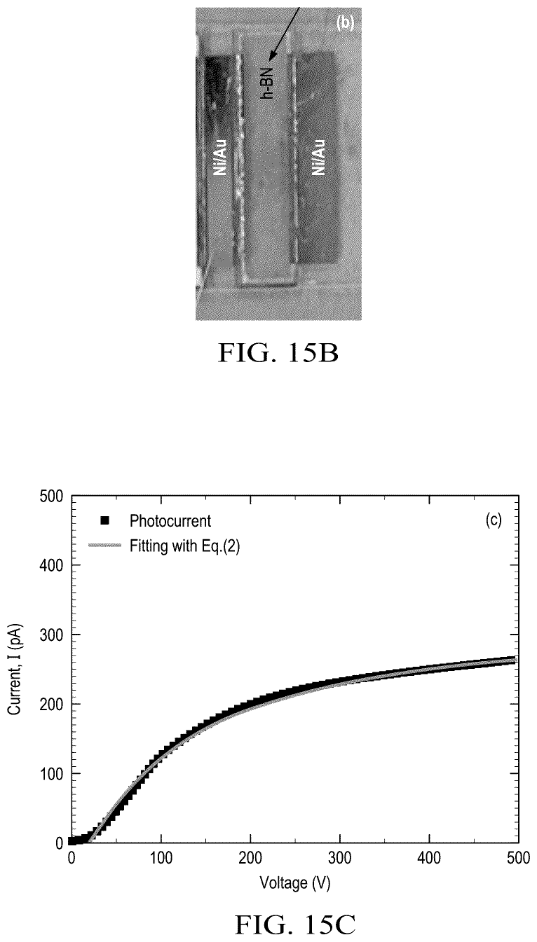

With the considerations discussed above, thermal neutron detection efficiency measurements were performed. To do so, as described previously [27-28, 31-32, 34, 54], a Californium-252 (²⁵²Cf) source from Frontier Technology was used as a neutron source. The calibrated fast neutron emission rate of ²⁵²Cf at the time of measurement was about 7.3×10⁵ neutrons per second (n/s). A high-density polyethylene (HDPE) cube moderator of 2.5 cm in thickness was used to house the neutron source and to convert fast neutrons to thermal neutrons. The h-BN detector and a commercial ⁶LiF filled 4 cm² micro-structured semiconductor neutron detector (MSND Domino™ V4) with a certified detection efficiency of 30% were placed side-by-side at 30 cm from the HDPE surface and exposed to thermal neutrons for the same duration of time, the detection efficiency (η) of the h-BN detector can be obtained by calibrating the counts against that of MSND. FIG. 16 shows the pulsed height spectra of a h-BN detector measured at 500 V. The spectrum (red) was measured under thermal neutron irradiation and the dark spectrum (blue) was also recorded in the absence of any radiation. Calibration against the MSND detector provided a thermal neutron detection efficiency of η=20% at 500 V for the detector shown in FIG. 15B. It has been shown that h-BN detectors exhibit no response to gamma photons when directly exposed to a 662 keV Cesium-137 source [28, 32, 51]. This is because BN is composed of low atomic number elements. However, the response of h-BN thick detectors to low energy (<100 keV) gamma photons merits further investigation. Furthermore, it is known that nitrogen absorbs neutron via N-14(n,p)C-14 reaction, which has been utilized previously in GaN for detecting neutrons [59]. However, the N-14(n,p)C-14 reaction cross-section of 2.4 Barn is negligibly small comparing to a value of 3480 Barns of thermal neutron absorption cross-section of ¹⁰B in using h-BN for thermal neutron detection here.

The most important parameter for gauging the overall material quality is the charge collection efficiency itself. In a photodetector, the charge collection efficiency is defined as the ratio of the number of charge carriers collected by the electrodes to the total number of charge carriers generated. However, in the case of a semiconductor neutron detector, the neutron will be counted as long as the neutron-generated signal can trigger a voltage pulse above the low-level discriminator (LLD) setting in the electronics. Therefore, the deviation from the theoretically expected efficiency of Equation 4 or the ratio of η/ηᵢ was used as a measure of an effective charge collection efficiency for the purpose of gauging the material quality and device performance. From the measured value of η20% and calculate value of ηᵢ from Equation 4 using the known thickness of 100 μm and λ(h-BN)=237 μm, a value of η/ηᵢ=59% at 500 V was obtained, while the prior state-of-the-art device (100 μm thick h-¹⁰BN thermal neutron detector with a detection efficiency of 59%) had a value of η/ηᵢ=67% at the same bias voltage of 500 V [28]. Given the fact that the development of HVPE growth of h-BN semi-bulk wafers is at such an early stage, it is believed that the demonstrated thermal natron detector performance, including the measured detection efficiency of 20% and effective charge collection efficiency of 59%, represents a very significant milestone in the development of cost-effective h-BN semi-bulk crystals and h-BN semiconductor neutron detectors.

In summary, the established GaN semi-bulk crystal growth technique of HVPE has been utilized to produce natural h-BN semi-bulk wafers. Electrical transport characterization results revealed that these HVPE grown materials possess an electrical resistivity of 1×10¹³ Ω·cm, and a charge carrier mobility and lifetime product of 2×10⁻⁴ cm²/V·s. Detectors fabricated from these materials have shown to deliver a thermal neutron detection efficiency of 20%, corresponding to 59% of charge collection efficiency, at an operating voltage of 500 V. The results indicate that HVPE is a promising growth method to produce h-BN semi-bulk crystals and h-BN semiconductor neutron detectors at a reduced manufacturing cost. There is no question that future h-BN detectors will replace the traditional He-3 gas detectors in certain application areas by offering obvious advantages of semiconductor technologies over gas detectors and opportunities for users to dedicate the scarce and expensive supply of He-3 gas to other application areas where substitutes of He-3 gas are not possible.

BN neutron detectors disclosed here possess all the intrinsic advantages of ultra-wide bandgap semiconductor devices:

BN detectors disclosed here possess the unique capability for detecting neutrons ranging from thermal to fast neutrons.

BN detectors disclosed here possess capability for distinguishing the nature of unknown neutron source between thermal and fast neutrons.

Small atomic numbers of B and N elements within BN. This provides highest possible energy deposition resulting from fast neutron elastic scattering among all semiconductors, which translates to higher charge generation. The same reason makes BN detectors insensitive to gamma rays.

Very large cross-section of ¹⁰B for thermal neutrons and high detection efficiencies for thermal neutron. Moreover, the total neutron path lengths in all 3 dimensions of the disclosed detectors are several orders of magnitude larger than the mean free path of 235 μm for thermal neutrons in natural hexagonal BN. As such, the intrinsic efficiency of the disclosed detector for thermal neutrons is almost 100% even with the use of natural BN.

Relatively large cross-section of ¹⁰B for epithermal neutrons and high detection efficiencies for epithermal neutron. Moreover, the total neutron path lengths in all 3 dimensions of the disclosed detectors are much larger than the mean free path of thermal neutrons in natural hexagonal BN. As such, the intrinsic efficiency of the disclosed detector for epithermal neutrons is reasonably high even with the use of natural BN. Ultrahigh bandgap (˜6 eV) of BN. This translates to extremely high electrical resistivity (>10¹³ Ω·cm) and low dark currents or counts, which makes BN very sensitive to detecting charge carriers generated by thermal neutron capture or by fast neutron elastic scattering.

BN possesses a high in-plane mobility for electrons and holes (in plane μₑ=μₕ=35 cm²/V·s) due to its layered structure, which supports a high charge collection efficiency.

As a semiconductor device, BN detectors possess the outstanding features of compactness, lightweight, and portable, and fast response time, which will be very useful for detecting nuclear fuel motion within test samples inserted in the core of a Transient Reactor Test Facility.

Flexible and excellent form factor due to the ability to produce freestanding h-BN films.

High sensitivity detectors are attainable by increasing the device area.

As an ultrahigh bandgap semiconductor with a small lattice constant, BN detectors are inherently suitable for operation in high temperature and harsh environments.

Semiconductor processing can be adopted with the potential for low-cost manufacturing.

In comparison, diamond in principle can be used to construct a similar type of fast neutron detector due to its wide bandgap, superior electrical and mechanical properties, and small atomic weight of carbon (A=12). However, diamond is not capable to replace the fast neutron detectors disclosed here. First, it is not feasible to produce such large wafers of diamond. Secondly, even if the growth of large diamond crystals can be realized, the cost will be enormous and way above practical uses. Assuming a diamond fast neutron detector can be produced with the same dimension (1 cm×1 cm×3 cm=3 cm³) to provide a comparable efficiency for fast neutrons as the proposed BN detector, the diamond detector would possess a weight of 3 cm³×3.5 g/cm³=10.5 g. This amount of diamond equivalently equals to 10.5 g/(0.2 g/carat)=52.5 carats, which will cost 10⁵ US dollars (based on $2,000 per carat). Lastly, although the cross-section of C atoms for fast neutrons is comparable to those of B and N atoms, diamond cannot detect thermal neutrons since the capture cross-section of C atoms for thermal neutrons is extremely small.

In comparison to another plausible competing candidate SiC, similar to diamond, SiC cannot detect thermal neutrons since the cross-sections of Si and C atoms for thermal neutrons are extremely small. In terms of fast neutron detection, the bandgap of SiC is not wide enough to provide a sufficiently high resistivity to support a low dark current or low background noise.

It is understood that particular embodiments described herein are shown by way of illustration and not as limitations of the invention. The principal features of this invention can be employed in various embodiments without departing from the scope of the invention. Those skilled in the art will recognize or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited features, elements, components, groups, integers, and/or steps, but do not exclude the presence of other unstated features, elements, components, groups, integers and/or steps. In embodiments of any of the compositions and methods provided herein, “comprising” may be replaced with “consisting essentially of” or “consisting of”. As used herein, the term “consisting” is used to indicate the presence of the recited integer (e.g., a feature, an element, a characteristic, a property, a method/process step or a limitation) or group of integers (e.g., feature(s), element(s), characteristic(s), property(ies), method/process steps or limitation(s)) only. As used herein, the phrase “consisting essentially of” requires the specified features, elements, components, groups, integers, and/or steps, but do not exclude the presence of other unstated features, elements, components, groups, integers and/or steps as well as those that do not materially affect the basic and novel characteristic(s) and/or function of the claimed invention.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB.

Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as still having the required characteristics and capabilities of the unmodified feature. In general, but subject to the preceding discussion, a numerical value herein that is modified by a word of approximation such as “about” may vary from the stated value by at least +1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

To aid the Patent Office, and any readers of any patent issued on this application in interpreting the claims appended hereto, applicants wish to note that they do not intend any of the appended claims to invoke paragraph 6 of 35 U.S.C. § 112, U.S.C. § 112 paragraph (f), or equivalent, as it exists on the date of filing hereof unless the words “means for” or “step for” are explicitly used in the particular claim.

For each of the claims, each dependent claim can depend both from the independent claim and from each of the prior dependent claims for each and every claim so long as the prior claim provides a proper antecedent basis for a claim term or element.

### REFERENCES

1. D. Reilly, N. Ensslin, H. Smith, and S. Kreiner, “Passive nondestructive assay of nuclear materials,” Los Alamos National Laboratory, Tech. Rep. NUREG/CR-5550 LA-UR-90-732, 1991.
2. R. C. Haight, “Fast-neutron detectors for nuclear physics experiments,” 2nd International workshop on Fast Neutron Detectors and Applications, Nov. 6-11 2011, EIN GEDI, Israel.
3. S. Kiss, S. Lipcsei, G. Házi, T. Parkó, I. Pós, and Z. Kálya, “New refueling neutron monitoring and reactivity measurement systems for Paks NPP,” 27^{th} International Conference Nuclear Energy for Europe, NENE Sep. 10-13, 2018.
4. B. M. van der Ende, L. Li, D. Godin, and B. Sur “Stand-off nuclear reactor monitoring with neutron detectors for safeguards and non-proliferation applications,” Nature Communications, 10, 1959 (2019).
5. R L Kouzes, “The 3He Supply Problem, April 2009; Pacific Northwest National Laboratory;” Prepared for the U.S. Department of Energy under Contract DE-AC05-76RL01830; pnl.gov/main/publications/exernal/technical reports/PNNL-18288.pdf
6. nrc.gov/docs/ML1122/ML11229A705.pdf
7. osti.gov/servlets/purl/732978.
8. nds.iaea.org/exfor/endf.htm.
9. A. Rose, “Sputtered boron films on silicon surface barrier detectors,” Nucl. Inst. Meth. 52 166 (1967).
10. R. J. Nikolic, C. L. Cheung, C. E. Reinhardt, T. F. Wang, “Future of semiconductor based thermal neutron detectors,” UCRL-PROC-219274, Nanotech 2006, Boston.
11. D. S. McGregor, R. T. Klann, H. K. Gersch, and Y. H. Yang, “Thin-film-coated bulk GaAs detectors for thermal and fast neutron measurements,” Nuclear Instruments and Methods in Physics Research A 466, 126 (2001).
12. H. K. Gersch, D. S. McGregor, and P. A. Simpson, “The effect of incremental gamma-ray doses and incremental fluences upon the performance of self-biased ¹⁰B-coated high-purity epitaxial GaAs thermal neutron detectors,” Nucl. Inst. Meth. Phys. Res. A 489 (2002).
13. N. LiCausi, J. Dingley, Y. Danon, J. Q. Lu, and I. B. Bhat, “A novel solid-state self-powered neutron detector,” Proc. SPIE 7079, 707908 (2008).
14. R. J. Nikolic, A. M. Conway, C. E. Reinhardt, R. T. Graff, T. F. Wang, N. Deo, and C. L. Cheung, “6:1 aspect ratio silicon pillar based thermal neutron detector filled with 10B,” Appl. Phys. Lett. 93, 133502 (2008).
15. R. J. Nikolic, Chin Li Cheung, C. E. Reinhardt, and T. F. Wang, “Roadmap for High Efficiency Solid State Neutron Detectors,” Proc. SPIE 6013, 601305 (2005).
16. A. M. Conway, T. F. Wang, N. Deo, C. L. Cheung, and R. J. Nikolic, “Numerical simulations of pillar structured solid state thermal neutron detector: efficiency and gamma discrimination,” IEEE Trans. Nucl. Sci 56, 2802 (2009).
17. R. Dahal, K. C. Huang, J. Clinton, N. LiCausi, J.-Q. Lu, Y. Danon, and I. Bhat, “Self-powered micro-structured solid state neutron detector with very low leakage current and high efficiency,” Appl. Phys. Lett. 100, 243507 (2012).
18. F. Wald and J. Bulitt, “Semiconductor neutron detectors,” U. S. Nat. Tech. Inform. Serv., AD Rep. (1973), (No. 771526/1GA), 36 pp.
19. K. P. Ananthanarayanan, P. J. Gielisse, and A. Choudry, “Boron compounds for thermal-neutron detection,” Nucl. Inst. Meth. 118, 45 (1974).
20. P. Lunca-Popa, J. I. Brand, S. Balaz, L. G. Rosa, N. M. Boag, M. Bai, B. W. Robertson, and P. A. Dowben, “Evidence for multiple polytypes of semiconducting boron carbide (C2B10) from electronic structure,” J. Phys. D. Appl. Phys. 38, 1248 (2005).
21. S. Adenwalla, P. Welsch, A. Harken, J. I. Brand, A. Sezer, and B. W. Robertson, “Boron/n-silicon carbide heterojunction diodes,” Appl. Phys. Lett. 79, 4357 (2001).
22. K. Osberg, N. Schemm, S. Balkir, J. O. Brand, M. S. Hallbeck, P. A. Dowben, and M. W. Hoffman, “A handheld neutron-detector sensor system utilizing a new class of boron carbide diode,” IEEE Sensor J. 6, 1531 (2006).
23. F. P. Doty, “Advanced digital detectors for neutron imagining,” Sandia Report SAND2003-8796 (Sandia National Laboratories, Livermore, 2003) and “Boron nitride solid-state neutron detector,” U.S. Pat. No. 6,727,504.
24. G. F. Knoll, “Radiation detection and measurement”, Glenn F. Knoll, 4th edition, John Wiley & Sons, (2010).
25. D. S. McGregor, S. L. Bellinger, J. C. Boyington, Y. Cheng, and R. G. Fronk, “Micro Structured Sensors for Neutron Detection,” Symposium on advanced sensors and modeling techniques for nuclear reactor safety, newprairiepress.org/cgi/viewcontent/cgi?article=1009&context=asemot.
26. Hongxing Jiang, Jingyu Lin, Jing Li, Avisek Maity, and Sam Grenadier, “Solid-state neutron detector,” U.S. Pat. No. 10,714,651 B2 and U.S. Pat. No. 11,195,968 B2.
27. A. Maity, S. J. Grenadier, J. Li, J. Y. Lin, and H. X. Jiang, “Hexagonal boron nitride neutron detectors with high detection efficiencies,” J. Appl. Phys. 123, 044501 (2018); ibib “High sensitivity hexagonal boron nitride lateral neutron detectors,” Appl. Phys. Lett. 114, 222102 (2019).
28. A. Maity, S. J. Grenadier, J. Li, J. Y. Lin, and H. X. Jiang, “High efficiency hexagonal boron nitride neutron detectors with 1 cm² detection areas,” Appl. Phys. Lett. 116, 142102 (2020).
29. S. J. Grenadier, A. Maity, J. Li, J. Y. Lin, and H. X. Jiang, “Lateral charge carrier transport properties of B-10 enriched hexagonal BN thick epilayers,” Appl. Phys. Lett. 115, 072108 (2019).
30. A. Maity, S. J. Grenadier, J. Li, J. Y. Lin, and H. X. Jiang, “Hexagonal boron nitride: Epitaxial growth and device applications,” Prog. Quantum. Electron. 76 100302 (2021).
31. S. J. Grenadier, A. Maity, J. Li, J. Y. Lin, and H. X. Jiang, “Electrical Transport Properties of Hexagonal Boron Nitride Epilayers,” Chapter 12 in “Ultrawide Bandgap Semiconductors,” Volume 107 in SEMICONDUCTORS AND SEMIMETALS (2021), edited by Yuji Zhao. Hardcover ISBN: 9780128228708.
32. A. Maity, T. C. Doan, J. Li, J. Y. Lin, and H. X. Jiang, “Realization of highly efficient hexagonal boron nitride neutron detectors,” Appl. Phys. Lett. 109, 072101 (2016).
33. J. Li, A. Maity, S. J. Grenadier, J. Y. Lin, and H. X. Jiang, “Charge collection in h-BN neutron detectors at elevated temperatures,” Appl. Phys. Lett. 118, 092102 (2021).
34. A. Maity, S. J. Grenadier, J. Li, J. Y. Lin, and H. X. Jiang, “Toward achieving flexible and high sensitivity hexagonal boron nitride neutron detectors,” Appl. Phys. Lett. 111, 033507 (2017).
35. nobelprize.org/prizes/physics/2014/press-release/
36. T. Sugino, K. Tanioka, S. Kawasaki, and J. Shirafuji, Jpn. Appl. Phys. 36, L463 (1997).
37. K. Watanabe, T. Taniguchi, and H. Kanda, Nature Mater. 3, 404 (2004).
38. K. Watanabe, T. Taniguchi, and H. Kanda, Nat. Photonics 3, 591 (2009).
39. H. X. Jiang and J. Y. Lin, Semicond. Sci. Technol. 29, 084003 (2014).
40. N. Alem, R. Erni, C. Kisielowski, M. D. Rossell, W. Gannett, and A. Zettl, Phys. Rev. B 80, 155425 (2009).
41. L. Song, L. Ci, H. Lu, P. B. Sorokin, C. Jin, J. Ni, A. G. Kvashnin, D. G. Kvashnin, J. Lou,
42. B. I. Yakobson, and P. M. Ajayan, Nano Lett. 10, 3209 (2010).
43. R. V. Gorbachev, I. Riaz, R. R. Nair, R. Jalil, L. Britnell, B. D. Belle, E. W. Hill, K. S. Novoselov, K. Watanabe, T. Taniguchi, A. K. Geim, and P. Blake, Small 7, 465 (2011)
44. L. Britnell, R. V. Gorbachev, R. Jalil, B. D. Belle, F. Schedin, A. Mishchenko, T. Georgiou, M. I. Katsnelson, L. Eaves, S. V. Morozov, N. M. R. Peres, J. Leist, A. K. Geim, K. S. Novoselov, and L. A. Ponomarenko, Science 335, 947 (2012).
45. T. T. Tran, C. Elbadawi, D. Totonjian, C. J. Lobo, G. Grosso, H. Moon, D. R. Englund, M. J. Ford, I. Aharonovich and M. Toth, ACS Nano 10, 7331 (2016).
46. N. R. Jungwirth, B. Calderon, Y. Ji, M. G. Spencer, M. E. Flatté and G. D. Fuchs, Nano Lett. 16, 6052 (2016).
47. Z. Shotan, H. Jayakumar, C. R. Considine, M. Mackoit, H. Fedder, J. Wrachtup, A. Alkauskas, M. W. Doherty, W. M. Menon and C. A. Meriles, ACS Photonics 3, 2490 (2016).
48. M. Kianinia, B. Regan, S. A. Tawfik, T. T. Tran, M. J. Ford, I. and M. Toth, ACS Photonics 4, 768 (2017).
49. O. Osberghaus, Zeitschrift fuer Physik 128, 366 (1950).
50. G. F. Knoll, “Radiation detection and measurement,” 4th edition, (John Wiley & Sons, 2010).
51. T. C. Doan, S. Majety, S. Grenadier, J. Li, J. Y. Lin, and H. X. Jiang, Nuclear Inst. and Methods in Physics Research Section A 748, 84 (2014).
52. I. C. Kizilyalli, O. B. Spahn, and Eric P Carlson, ECS Trans. 109, 3 (2022).
53. D. S. McGregor, S. L. Bellinger, R. G. Fronk, L. Henson, D. Huddleston, T. Ochs, J. K. Shultis, T. J. Sobering, and R. D. Taylor, Radiation Physics and Chemistry, 116, 32 (2015).
54. L. Weston, D. Wickramaratne, M. Mackoit, A. Alkauskas, and C. G. Van de Walle, Phys. Rev. B97, 214104 (2018).
55. H. Fujikura, T. Konno, T. Kimura, Y. Narita, and F. Horikir, Appl. Phys. Lett. 117, 012103 (2020).
56. K. Ohnishi, N. Fujimoto, S. Nitta, H. Watanabe, S. Lu, M. Deki, Y. Honda, and H. Amano, J. Appl. Phys. 132, 145703 (2022).
57. M. A. McKay, J. Li, J. Y. Lin, and H. X. Jiang, J. Appl. Phys. 127, 0531032 (2020).
58. A. Many, J. Phys. Chem. Solids 26, 575 (1965).
59. J. Qiu, E. Katz, C. H. Lin, L. Cao, and L. J. Brillson, Radiation Effects and Defects in Solids 168, 924 (2013).

1. A neutron detector comprising:
two or more boron nitride (BN) strips electrically connected in parallel or series.

2. The neutron detector of claim 1, wherein:
each of the two or more BN strips has a width (W) of about 1 to 10 mm, a length (L) of about 10 to 50 mm, and a thickness (d) or height (H) of about 0.1 mm to 10 mm thick;
the two or more BN strips comprise Boron-10 enriched boron nitride or natural BN crystals;
the two or more BN strips further comprise 1, 2, 3, 4, 5, 6, 7, 8, 9, 10, 11, 12 or more intermediate BN strips.

3-4. (canceled)

5. The neutron detector of claim 1, further comprising a housing enclosing the two or more BN strips.

6. The neutron detector of claim 5, further comprising a gamma-ray shield disposed around the housing.

7. The neutron detector of claim 1, wherein the two or more BN strips comprise two or more BN strips stacked on one another.

8. The neutron detector of claim 7, further comprising:
a metal contact disposed on a top and a bottom of the two or more BN strips; and
the two or more BN strips are connected together through the metal contacts in parallel or series to support a charge transport in a vertical direction with respect to planes of the two or more BN strips.

9. The neutron detector of claim 7, further comprising:
an intermediate substrate disposed in between each of the two or more BN strips;
a lower substrate disposed on a bottom of a lower BN strip of the two or more BN strips;
a first metal contact disposed on a first longitudinal side of each of the two or more BN strips;
a second metal contact disposed on a second longitudinal side of each of the two or more BN strips; and
wherein the first metal contacts and second metal contacts are used to electrically connect the two or more BN strips in parallel to support a charge transport in a lateral direction with respect to planes of the two or more BN strips.

10. The neutron detector of claim 9, wherein each intermediate substrate and the lower substrate comprise sapphire, pyrolytic BN, free-standing hexagonal BN, SiC, or polycrystalline diamond.

11. The neutron detector of claim 9, wherein the lower substrate is larger than each intermediate substrate, and the intermediate substrates become progressively smaller from the lower substrate to an upper BN strip.

12. The neutron detector of claim 9, further comprising one or more buffer layers disposed on top of the lower substrate and each intermediate substrate.

13. The neutron detector of claim 12, further comprising one or more epitaxial layer templates disposed on top of each of the one or more buffer layers.

14. The neutron detector of claim 13, wherein the one or more epitaxial layer templates comprise AlN, BN, GaN or diamond materials.

15. The neutron detector of claim 1, further comprising:
a substrate;
the two or more BN strips comprise two or more BN strips disposed on the substrate with a gap between the two or more BN strips;
a first metal contact disposed on a first longitudinal side of each of the two or more BN strips;
a second metal contact disposed on a second longitudinal side of each of the two or more BN strips; and
wherein the first metal contacts and second metal contacts are used to electrically connect the two or more BN strips in parallel to support a charge transport in a lateral direction with respect to the planes of two or more BN strips.

16. The neutron detector of claim 15, wherein the gap comprises 0.1 to 2 mm.

17. The neutron detector of claim 15, further comprising a housing enclosing the two or more BN strips.

18. The neutron detector of claim 17, further comprising a gamma-ray shield disposed around the housing.

19. The neutron detector of claim 15, further comprising:
the substrate comprises a first substrate having a first metal pad connected to the first metal contacts and a second metal pad connected to the second metal contacts;
the two or more BN strips comprise two or more first BN strips;
one or more BN assemblies disposed below the first substrate, each of the one or more BN assemblies comprise:
a second BN strip,
a second substrate disposed below the second BN strip,
a third metal contact disposed on a first longitudinal side of the second BN strip, and
a fourth metal contact disposed on a second longitudinal side of the second BN strip; and
the first metal pad, the second metal pad, the third metal contacts, the fourth metal contacts are used to electrically connect the two or more first BN strips and each second BN strip in parallel.

20. The neutron detector of claim 19, wherein the first substrate and the second substrate comprise sapphire, pyrolytic BN, free-standing hexagonal BN, SiC, or polycrystalline diamond.

21. The neutron detector of claim 19, further comprising one or more buffer layers disposed on top of the first substrate and the second substrate.

22. The neutron detector of claim 21, further comprising one or more epitaxial layer templates disposed on top of each of the one or more buffer layers.

23. The neutron detector of claim 22, wherein the one or more epitaxial layer templates comprise AlN, BN, GaN or diamond materials.

24. A method for detecting neutrons using the neutron detector of claim 1.

25. The method of claim 24, wherein:
the detected neutrons have energies from meV to tens of MeV; or
the detected neutrons comprise thermal to fast neutrons.

26. (canceled)

27. The method of claim 24, further comprising converting the neutrons from fast neutrons to thermal neutrons by adding a block of HDPE material around the neutron detector to distinguish thermal neutrons from fast neutrons.

28. The method of claim 27, further comprising determining whether a neutron source comprises a thermal neutron source or a fast neutron source based on a change in a counting rate of the thermal neutrons after adding the block of HDPE material.

29. A method of fabricating a boron nitride (BN) layer comprising:
depositing one or more buffer layers on a substrate; and
growing the BN layer on the one or more buffer layers.

30. The method of claim 29, wherein:
the substrate comprises sapphire, pyrolytic BN, free-standing hexagonal BN, SiC, or polycrystalline diamond,
the BN layer comprises Boron-10 enriched boron nitride or natural BN crystals;
a thickness of the BN layer comprises 0.1 to 10 mm; or
the BN layer is grown using hydride vapor phase epitaxy (HVPE), sputtering, pulsed laser deposition (PLD), chemical vapor deposition (CVD), or metal organic vapor deposition (MOCVD).

31-33. (canceled)

34. The method of claim 29, further comprising depositing one or more epitaxial layer templates on top of the one or more buffer layers prior to growing the BN layer.

35. The method of claim 34, wherein the one or more epitaxial layer templates comprise AlN, BN, GaN or diamond materials.

36. The method of claim 29, further comprising:
removing the BN layer; and
dicing the BN layer into BN strips.

37. The method of claim 36, further comprising mounting one or more of the BN strips on sapphire substrate.

38. The method of claim 37, further comprising depositing one or more metal contacts on the BN strips.
